(19) United States
(12) Patent Application Publication
(10) Pub. No.: US 2024/0379715 A1
(43) Pub. Date: Nov. 14, 2024

(54) LIGHT DETECTION DEVICE AND ELECTRONIC DEVICE

(71) Applicant: SONY SEMICONDUCTOR SOLUTIONS CORPORATION, Kanagawa (JP)

(72) Inventor: Satoe MIYATA, Kanagawa (JP)

(73) Assignee: SONY SEMICONDUCTOR SOLUTIONS CORPORATION, Kanagawa (JP)

(21) Appl. No.: 18/686,815

(22) PCT Filed: Mar. 11, 2022
(86) PCT No.: PCT/JP2022/010929

§ 371 Date: Feb. 26, 2024

(30) Foreign Application Priority Data
Sep. 7, 2021 (JP) 2021-145108

(51) Int. Cl. H01L 27/146; G01J 1/44; H04N 25/77; H04N 25/79

(52) U.S. Cl. CPC H01L 27/14632; G01J 1/44; H01L 27/14687; G01J 2001/4466; H04N 25/77; H04N 25/79

(57) ABSTRACT

A light detection device capable of relaxing an electric field at an interface between an insulating film and a semiconductor substrate. The present technology includes a semiconductor substrate, a first trench and a second trench each having a lattice shape and provided on a first surface of the semiconductor substrate, an insulating film covering inner side surfaces of the first and second trenches and the first surface, an anode electrode embedded in the first trench, P type, P+ type, and N+ type semiconductor regions, a cathode contact in an element region, and a cathode electrode. The insulating film includes at least a first region and a second region. The second region includes a portion at a depth at which a distance between a third semiconductor region and a first electrode is minimized. A dielectric constant of the second region is lower than a dielectric constant of the first region.

### TECHNICAL FIELD

The present technology (technology according to the present disclosure) relates to a light detection device and an electronic device.

### BACKGROUND ART

Conventionally, a light detection device including a semiconductor substrate on which a plurality of single photon avalanche diodes (SPADs) is arranged has been proposed (See, for example, Patent Document 1.). In the light detection device described in Patent Document 1, a first trench provided on a front surface of a semiconductor substrate and a second trench provided at a bottom of the first trench are provided, an insulating film covering an inner side surface of the first trench and an anode electrode filling the inside of the first trench are arranged in the first trench, and an anode contact in contact with the anode electrode is provided at the bottom of the first trench. Therefore, by increasing a distance between the anode contact, and a cathode contact and an N+ type semiconductor region in a thickness direction of the semiconductor substrate, an electric field between the anode contact, and the cathode contact and the N+ type semiconductor region is relaxed, and occurrence of defects due to a high electric field such as edge breakdown is suppressed.

### CITATION LIST

### Patent Document

Patent Document 1: WO 2020/203222

### SUMMARY OF THE INVENTION

### Problems to be Solved by the Invention

However, in the light detection device described in Patent Document 1, for example, in a case of miniaturization, a distance between the insulating film and the N+ type semiconductor region becomes small. Here, a reverse bias voltage that is a high voltage is applied to the anode electrode in contact with the insulating film. Therefore, an electric field becomes strong at an interface between the insulating film and the semiconductor substrate, and there has been a possibility that edge breakdown is likely to occur.

An object of the present disclosure is to provide a light detection device and an electronic device capable of relaxing an electric field at an interface between an insulating film and a semiconductor substrate.

### Solutions to Problems

A light detection device of the present disclosure includes: (a) a semiconductor substrate; (b) a first trench having a lattice shape and provided on a first surface of the semiconductor substrate; (c) a second trench having a lattice shape, provided at a bottom of the first trench and extending along the bottom; (d) an insulating film covering each of inner side surfaces of the first and second trenches and the first surface; (e) a photoelectric conversion region provided in an element region obtained by partitioning the semiconductor substrate by the first and second trenches, the photoelectric conversion region photoelectrically converting incident light to generate a charge; (f) a first semiconductor region provided in the element region and surrounding the photoelectric conversion region; (g) a first contact provided at the bottom of the first trench and in contact with the first semiconductor region; (h) a first electrode disposed in the first trench and in contact with the first contact; (i) a second semiconductor region provided in a region in contact with a surface of the first semiconductor region on the first surface side in the element region and having a first conductivity type same as a conductivity type of the first semiconductor region; (j) a third semiconductor region provided in a region in contact with a surface of the second semiconductor region on the first surface side in the element region and having a second conductivity type opposite to the first conductivity type; (k) a second contact provided on the first surface and in contact with the third semiconductor region; and (l) a second electrode in contact with the second contact, in which (m) the insulating film includes at least a first region and a second region, the second region is a region including a portion whose depth from the first surface is located at a depth at which a distance between the third semiconductor region and the first electrode is minimized, and a dielectric constant of the second region is lower than a dielectric constant of the first region.

Another light detection device of the present disclosure includes: (a) a semiconductor substrate; (b) a first trench having a lattice shape and provided on a first surface of the semiconductor substrate; (c) a second trench having a lattice shape, provided at a bottom of the first trench and extending along the bottom; (d) an insulating film covering each of inner side surfaces of the first and second trenches and the first surface; (e) a photoelectric conversion region provided in an element region obtained by partitioning the semiconductor substrate by the first and second trenches, the photoelectric conversion region photoelectrically converting incident light to generate a charge; (f) a first semiconductor region provided in the element region and surrounding the photoelectric conversion region; (g) a first contact provided at the bottom of the first trench and in contact with the first semiconductor region; (h) a first electrode disposed in the first trench and in contact with the first contact; (i) a second semiconductor region provided in a region in contact with a surface of the first semiconductor region on the first surface side in the element region and having a first conductivity type same as a conductivity type of the first semiconductor region; (j) a third semiconductor region provided in a region in contact with a surface of the second semiconductor region on the first surface side in the element region and having a second conductivity type opposite to the first conductivity type; (k) a second contact provided on the first surface and in contact with the third semiconductor region; and (l) a second electrode in contact with the second contact, in which (m) a portion of the insulating film whose depth from the first surface is located at a depth at which a distance between the third semiconductor region and the first electrode is minimized is formed by using a low dielectric constant material having a relative dielectric constant of 3.5 or less.

An electronic device of the present disclosure includes a light detection device including: (a) a semiconductor substrate; (b) a first trench having a lattice shape and provided on a first surface of the semiconductor substrate; (c) a second trench having a lattice shape, provided at a bottom of the first trench and extending along the bottom; (d) an insulating film covering each of inner side surfaces of the first and second trenches and the first surface; (e) a photoelectric conversion region provided in an element region obtained by partitioning the semiconductor substrate by the first and second trenches, the photoelectric conversion region photoelectrically converting incident light to generate a charge; (f) a first semiconductor region provided in the element region and surrounding the photoelectric conversion region; (g) a first contact provided at the bottom of the first trench and in contact with the first semiconductor region; (h) a first electrode disposed in the first trench and in contact with the first contact; (i) a second semiconductor region provided in a region in contact with a surface of the first semiconductor region on the first surface side in the element region and having a first conductivity type same as a conductivity type of the first semiconductor region; (j) a third semiconductor region provided in a region in contact with a surface of the second semiconductor region on the first surface side in the element region and having a second conductivity type opposite to the first conductivity type; (k) a second contact provided on the first surface and in contact with the third semiconductor region; and (l) a second electrode in contact with the second contact, in which (m) the insulating film includes at least a first region and a second region, the second region is a region including a portion whose depth from the first surface is located at a depth at which a distance between the third semiconductor region and the first electrode is minimized, and a dielectric constant of the second region is lower than a dielectric constant of the first region.

Another electronic device of the present disclosure includes a light detection device including: (a) a semiconductor substrate; (b) a first trench having a lattice shape and provided on a first surface of the semiconductor substrate; (c) a second trench having a lattice shape, provided at a bottom of the first trench and extending along the bottom; (d) an insulating film covering each of inner side surfaces of the first and second trenches and the first surface; (e) a photoelectric conversion region provided in an element region obtained by partitioning the semiconductor substrate by the first and second trenches, the photoelectric conversion region photoelectrically converting incident light to generate a charge; (f) a first semiconductor region provided in the element region and surrounding the photoelectric conversion region; (g) a first contact provided at the bottom of the first trench and in contact with the first semiconductor region; (h) a first electrode disposed in the first trench and in contact with the first contact; (i) a second semiconductor region provided in a region in contact with a surface of the first semiconductor region on the first surface side in the element region and having a first conductivity type same as a conductivity type of the first semiconductor region; (j) a third semiconductor region provided in a region in contact with a surface of the second semiconductor region on the first surface side in the element region and having a second conductivity type opposite to the first conductivity type; (k) a second contact provided on the first surface and in contact with the third semiconductor region; and (l) a second electrode in contact with the second contact, in which (m) a portion of the insulating film whose depth from the first surface is located at a depth at which a distance between the third semiconductor region and the first electrode is minimized is formed by using a low dielectric constant material having a relative dielectric constant of 3.5 or less.

### BRIEF DESCRIPTION OF DRAWINGS

FIG. 1 is a schematic configuration diagram illustrating an entire electronic device equipped with a solid-state imaging device according to the first embodiment.

FIG. 2 is a schematic configuration diagram illustrating the entire solid-state imaging device.

FIG. 3 is a diagram illustrating a circuit configuration of a SPAD pixel.

FIG. 4 is a view illustrating a cross-sectional configuration of the solid-state imaging device.

FIG. 5 is an enlarged view of a substantial part of FIG. 4.

FIG. 6 is a view illustrating a cross-sectional configuration of the SPAD pixel cut along line A-A in FIG. 4.

FIG. 7 is a view illustrating a cross-sectional configuration of the SPAD pixel cut along line B-B in FIG. 4.

FIG. 8 is a view illustrating a result of a simulation in which an electric field intensity distribution of a semiconductor substrate is analyzed in a case where an entire region of an insulating film includes silicon oxide.

FIG. 9 is a diagram illustrating a potential state between an anode electrode and a P+ type semiconductor region at a depth at which a distance between the N+ type semiconductor region and the anode electrode is minimized.

FIG. 10 is a view illustrating a result of a simulation in which an electric field intensity distribution of the semiconductor substrate is analyzed in the case where the entire region of the insulating film includes silicon oxide.

FIG. 11 is a process cross-sectional view illustrating a manufacturing method for the solid-state imaging device.

FIG. 12 is a process cross-sectional view illustrating the manufacturing method for the solid-state imaging device.

FIG. 13 is a process cross-sectional view illustrating the manufacturing method for the solid-state imaging device.

FIG. 14 is a process cross-sectional view illustrating the manufacturing method for the solid-state imaging device.

FIG. 15 is a process cross-sectional view illustrating the manufacturing method for the solid-state imaging device.

FIG. 16 is a process cross-sectional view illustrating the manufacturing method for the solid-state imaging device.

FIG. 17 is a process cross-sectional view illustrating the manufacturing method for the solid-state imaging device.

FIG. 18 is a process cross-sectional view illustrating the manufacturing method for the solid-state imaging device.

FIG. 19 is a process cross-sectional view illustrating the manufacturing method for the solid-state imaging device.

FIG. 20 is a process cross-sectional view illustrating the manufacturing method for the solid-state imaging device.

FIG. 21 is a process cross-sectional view illustrating the manufacturing method for the solid-state imaging device.

FIG. 22 is a process cross-sectional view illustrating the manufacturing method for the solid-state imaging device.

FIG. 23 is a process cross-sectional view illustrating the manufacturing method for the solid-state imaging device.

FIG. 24 is a view illustrating a cross-sectional configuration of a solid-state imaging device according to a modification.

FIG. 25 is a view illustrating a cross-sectional configuration of a solid-state imaging device according to a modification.

FIG. 26 is a view illustrating a cross-sectional configuration of a solid-state imaging device according to a modification.

FIG. 27 is a view illustrating a cross-sectional configuration of a solid-state imaging device according to a modification.

FIG. 28 is a view illustrating a cross-sectional configuration of a solid-state imaging device according to a modification.

FIG. 29 is a view illustrating a cross-sectional configuration of a solid-state imaging device according to a modification.

FIG. 30 is a view illustrating a cross-sectional configuration of a solid-state imaging device according to a modification.

FIG. 31 is a view illustrating a cross-sectional configuration of a solid-state imaging device according to a modification.

FIG. 32 is a view illustrating a cross-sectional configuration of a solid-state imaging device according to a modification.

FIG. 33 is a view illustrating a cross-sectional configuration of a solid-state imaging device according to a modification.

FIG. 34 is a view illustrating a cross-sectional configuration of a solid-state imaging device according to a modification.

FIG. 35 is a view illustrating a cross-sectional configuration of a solid-state imaging device according to a modification.

FIG. 36 is a view illustrating a cross-sectional configuration of a solid-state imaging device according to a modification.

### MODE FOR CARRYING OUT THE INVENTION

The inventors of the present disclosure have found the following problems in the light detection device described in Patent Document 1.

As device requirements of the light detection device of the type described in Patent Literature 1, there are two requirements of (1) suppression of edge breakdown and (2) enhancement of light detection efficiency. From the viewpoint of (1), it is conceivable to increase a distance between an insulating film in contact with an anode electrode and an N+ type semiconductor region in order to relax an electric field. Furthermore, from the viewpoint of (2), it is conceivable to widen the N+ type semiconductor region in a lateral direction to increase an area of an amplification region. However, for example, in a case where it is considered to miniaturize the light detection device, (1) and (2) have a trade-off relationship.

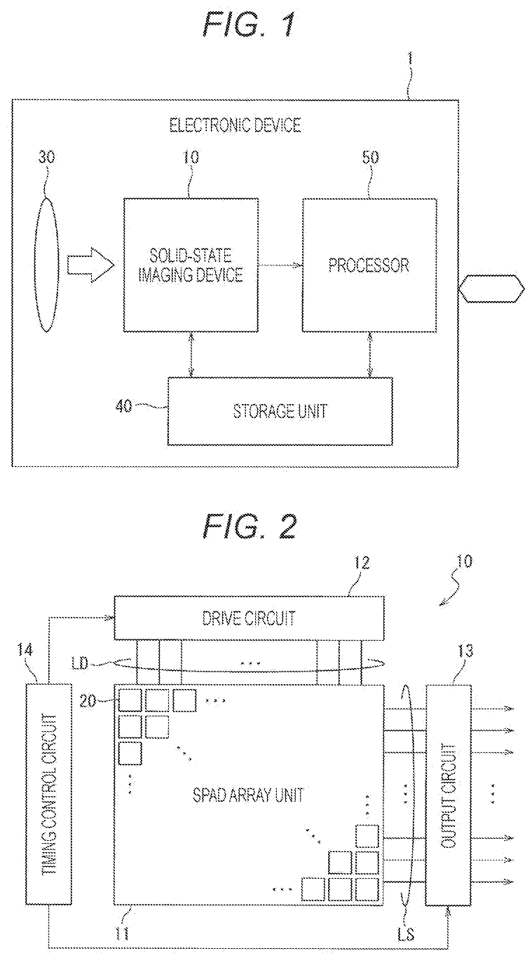

Hereinafter, an example of a light detection device and an electronic device according to embodiments of the present disclosure will be described with reference to FIGS. 1 to 36. The embodiments of the present disclosure will be described in the following order. Note that, the present disclosure is not limited to the following examples. Furthermore, the effects described in the present specification are merely examples and are not limited to any particular effects, and there may be some other effects.
1. First embodiment
1-1 Electronic device
1-2 Solid-state imaging device
1-3 Cross-sectional configuration of solid-state imaging device
1-4 Configuration of substantial part
1-5 Manufacturing method
1-6 Modifications

### 1. First Embodiment

A solid-state imaging device (in a broad sense, a “light detection device”) and an electronic device according to a first embodiment will be described in detail with reference to the drawings.

### 1-1 Electronic Device

FIG. 1 is a schematic configuration diagram illustrating an entire electronic device 1 equipped with a solid-state imaging device 10 according to the first embodiment. As illustrated in FIG. 1, the electronic device 1 includes an imaging lens 30, the solid-state imaging device 10, a storage unit 40, and a processor 50.

The imaging lens 30 condenses incident light (image light from a subject) and forms an image on a light receiving surface of the solid-state imaging device 10. The light receiving surface is a surface on which photoelectric conversion elements of the solid-state imaging device 10 are arranged.

The solid-state imaging device 10 photoelectrically converts the incident light to generate image data. Furthermore, the solid-state imaging device 10 executes predetermined signal processing such as noise removal and white balance adjustment on the generated image data.

The storage unit 40 includes, for example, a flash memory, a dynamic random access memory (DRAM), a static random access memory (SRAM), or the like. The storage unit 40 records image data generated by the solid-state imaging device 10, an operating system, and the like.

The processor 50 includes, for example, a central processing unit (CPU) or the like. The CPU may include an application processor that executes an operating system, various application software, and the like, a graphics processing unit (GPU), a baseband processor, and the like. The processor 50 executes various processes as necessary on image data generated by the solid-state imaging device 10, image data read from the storage unit 40, or the like, executes display to the user, and transmits the image data to the outside via a predetermined network.

### 1-2 Solid-state Imaging Device

FIG. 2 is a schematic configuration diagram illustrating the entire solid-state imaging device 10 according to the first embodiment. The solid-state imaging device 10 in FIG. 2 is a complementary metal-oxide-semiconductor (CMOS) solid-state imaging device (image sensor). The CMOS solid-state imaging device is a solid-state imaging device created by applying or partially using a CMOS process. Note that in the first embodiment, the solid-state imaging device 10 of a so-called back-illuminated type in which a surface on a side opposite to an element formation surface in the semiconductor substrate is a light incident surface is exemplified, but the present technology is not limited to the back-illuminated type, and a so-called front-illuminated type in which the element formation surface is the light incident surface may be used.

As illustrated in FIG. 2, the solid-state imaging device 10 includes a SPAD array unit 11, a drive circuit 12, an output circuit 13, and a timing control circuit 14.

The SPAD array unit 11 includes a plurality of SPAD pixels 20 arranged in a matrix. To the plurality of SPAD pixels 20, a pixel drive line LD (a line extending in the vertical direction in FIG. 2) is connected for every column, and an output signal line LS (a line extending in the horizontal direction in FIG. 2) is connected for every row. One end of the pixel drive line LD is connected to an output end of the drive circuit 12 corresponding to each column. Furthermore, one end of the output signal line LS is connected to an input end of the output circuit 13 corresponding to each row.

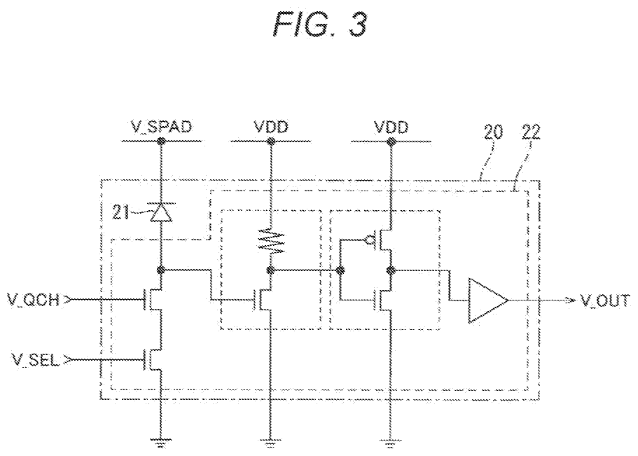

The drive circuit 12 includes a shift register, an address decoder, and the like, and drives the SPAD pixels 20 of the SPAD array unit 11 all at once or in units of columns or the like. Then, the drive circuit 12 applies a selection control voltage V_SEL (see FIG. 3) to the pixel drive line LD corresponding to the column to be read to select the SPAD pixels 20 to be used for detecting incidence of photons in units of columns.

A signal (hereinafter, also referred to as a “detection signal”) V_OUT output from each SPAD pixel 20 of the column selected by the drive circuit 12 is input to the output circuit 13 through each of the output signal lines LS. The output circuit 13 outputs the detection signal V_OUT input from each SPAD pixel 20 to the external storage unit 40 or the external processor 50 illustrated in FIG. 1 as a pixel signal.

The timing control circuit 14 includes a timing generator or the like that generates various timing signals, and controls the drive circuit 12 and the output circuit 13 on the basis of the timing signal generated.

FIG. 3 is a diagram illustrating a circuit configuration of the SPAD pixel 20. As illustrated in FIG. 3, the SPAD pixel 20 includes a photodiode 21 as a light receiving element and a readout circuit 22 that detects incidence of a photon on the photodiode 21. The photodiode 21 is a SPAD, and operates in Geiger mode when a reverse bias voltage V_SPAD equal to or higher than a breakdown voltage is applied between an anode and a cathode of the SPAD, and generates an avalanche current when photons are incident while operating in Geiger mode.

### 1-3 Cross-sectional Configuration of Solid-state Imaging Device

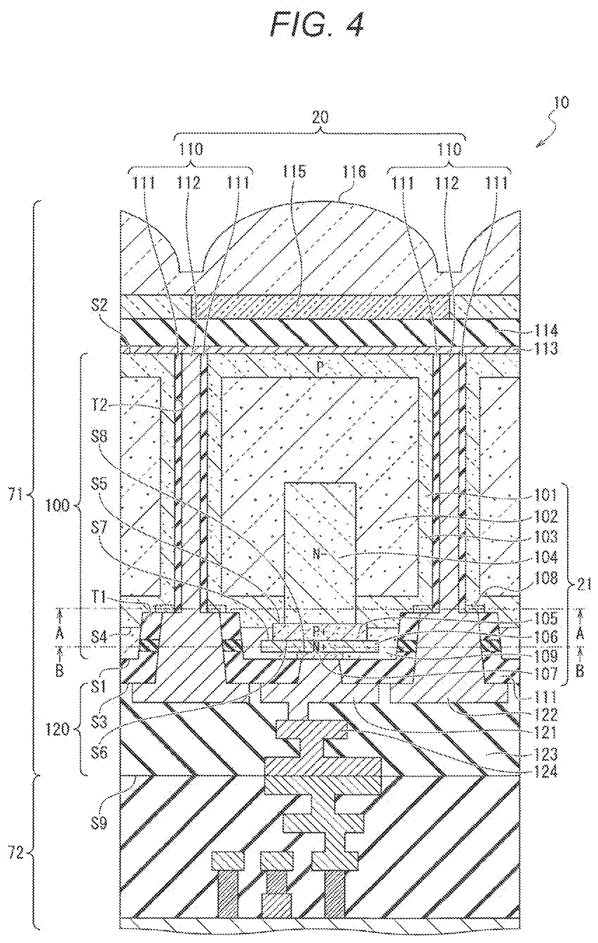

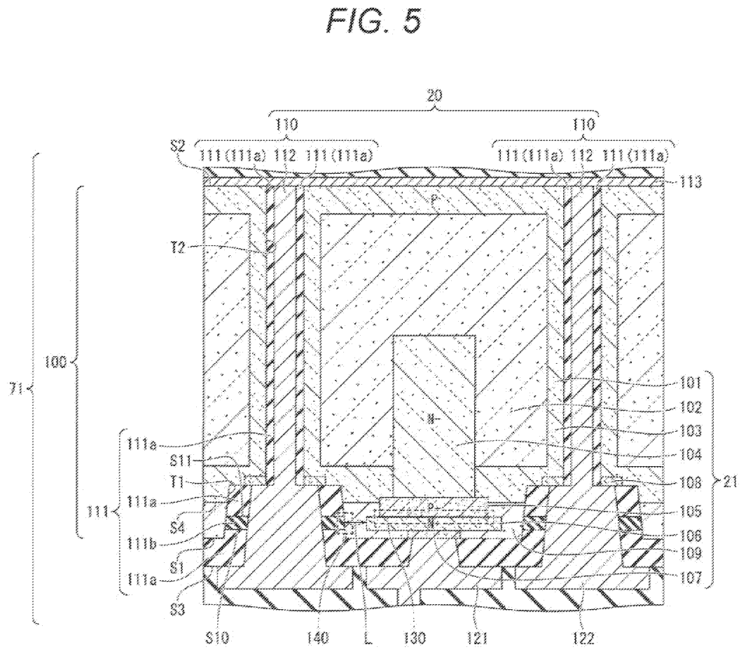

FIG. 4 is a view illustrating a cross-sectional configuration of the solid-state imaging device 10. Furthermore, FIG. 5 is an enlarged view illustrating a cross-sectional configuration of the photodiode 21 and the vicinity thereof in FIG. 4. As illustrated in FIG. 4, the solid-state imaging device 10 has a structure in which a light receiving chip 71 and a circuit chip 72 are vertically stacked. The light receiving chip 71 is a semiconductor chip including the SPAD array unit 11 (see FIG. 2) in which the SPAD pixels 20 are arranged. Furthermore, the circuit chip 72 is a semiconductor chip on which the readout circuit 22 (see FIG. 3) is arranged. Note that peripheral circuits such as the drive circuit 12, the output circuit 13, and the timing control circuit 14 illustrated in FIG. 2 may be arranged on the circuit chip 72.

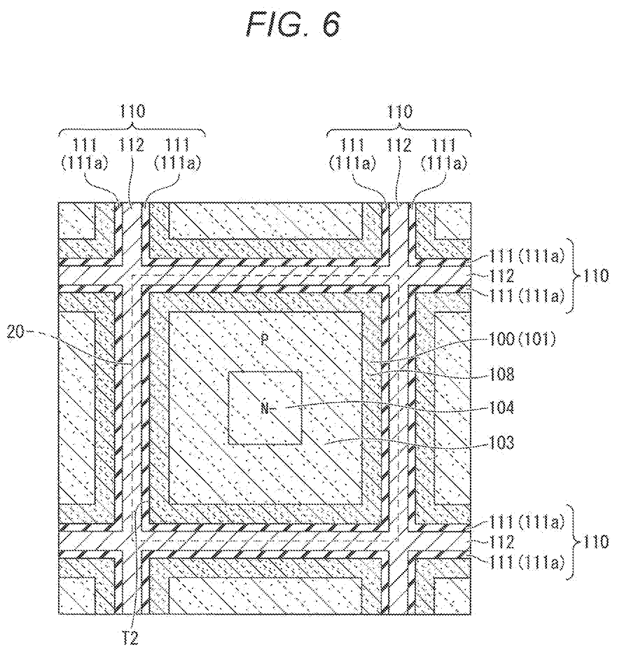

The photodiode 21 of the SPAD pixel 20 is provided on a semiconductor substrate 100 constituting the light receiving chip 71. The semiconductor substrate 100 is partitioned into a plurality of element regions 101 by an element isolation portion 110 having a lattice shape as viewed from a back surface S2 (upper surface in FIG. 4. light incident surface) (see FIG. 6). FIG. 6 is a view illustrating a cross-sectional configuration of the SPAD pixel 20 cut along line A-A in FIG. 4. The photodiode 21 is provided in each of the element regions 101.

The element isolation portion 110 defining each photodiode 21 is provided in a trench (hereinafter, also referred to as a “second trench T2”) penetrating the semiconductor substrate 100 from the front surface S1 (lower surface in FIG. 4. in a broad sense, a “first surface”) to the bottom of a first trench T1 to be described later. Each element isolation portion 110 includes an insulating film 111 covering an inner side surface of the second trench T2 and a light shielding film 112 filling an inside of the second trench T2. The insulating film 111 covers the inner side surface of the second trench T2 and the front surface S1 of the semiconductor substrate 100 in addition to the inner side surface of the second trench T2. A portion covering the inner side surface of the second trench T2 and a portion covering the front surface S1 of the semiconductor substrate 100 are continuously provided. Furthermore, a second region 111b (see FIG. 5) including a low dielectric constant material having a dielectric constant lower than that of a first region 111a as described later is provided in the portion covering the inner side surface of the second trench T2. A film thickness of the insulating film 111 covering the inner side surface of the second trench T2 depends on a voltage value of the reverse bias voltage V_SPAD applied between the anode and the cathode, but may be, for example, about 10 nm to 20 nm. Further, a film thickness (thickness in the groove width direction) of the light shielding film 112 depends on the material or the like used for the light shielding film 112, but may be, for example, about 150 nm.

Furthermore, trenches (hereinafter, also referred to as the “first trench T1”) provided in a lattice shape along the element isolation portion 110 are provided on the front surface S1 of the semiconductor substrate 100. The first trench T1 is connected to the second trench T2 at the bottom. Therefore, the lattice-shaped second trench T2 extending along the bottom of the first trench T1 is provided at the bottom of the first trench T1. Furthermore, the groove width of the first trench T1 is larger than the groove width of the second trench T2.

The first trench T1 includes an insulating film 111 covering the inner side surface of the first trench T1 and an anode electrode 122 (in a broad sense, a “first electrode”) filling an inside of the first trench T1. Therefore, at least a part of the anode electrode 122 is disposed in the first trench T1. A film thickness of the insulating film 111 covering the inner side surface of the first trench T1 depends on a voltage value of the reverse bias voltage V_SPAD applied between the anode and the cathode, but may be, for example, about several hundred nm. Further, a thickness in the groove width direction of the anode electrode 122 depends on the material or the like used for the anode electrode 122, but may be, for example, about several hundred nm. The anode electrode 122 protrudes from an opening of the first trench T1, and the protruding portion spreads so as to be in contact with a front surface S3 (lower surface in FIG. 4) of the insulating film 111 covering the front surface S1 of the semiconductor substrate 100.

Furthermore, an opening for exposing a cathode contact 107 is provided in a portion of the insulating film 111 covering the front surface S1 of the semiconductor substrate 100, and a cathode electrode 121 in contact with the cathode contact 107 is provided in the opening. The cathode electrode 121 protrudes from the opening of the insulating film 111, and the protruding portion spreads so as to be in contact with the front surface S3 of the insulating film 111.

Here, by using the same conductive material having a light shielding property for the light shielding film 112 and the anode electrode 122, the light shielding film 112 and the anode electrode 122 can be formed in the same process. Moreover, by using the same conductive material as the light shielding film 112 and the anode electrode 122 for the cathode electrode 121, the light shielding film 112, the anode electrode 122, and the cathode electrode 121 can be formed in the same process. As the conductive material having a light shielding property, for example, tungsten (W), aluminum (Al), an aluminum alloy, or copper (Cu) can be used.

Note that the material of the light shielding film 112 in the second trench T2 is not limited to the conductive material, and for example, a high refractive index material having a refractive index higher than that of the semiconductor substrate 100, a low refractive index material having a refractive index lower than that of the semiconductor substrate 100, or the like can be used.

Further, since the material of the cathode electrode 121 is not required to have a light shielding property, a conductive material such as copper (Cu) may be used, for example, instead of the conductive material having a light shielding property.

Each photodiode 21 includes a photoelectric conversion region 102, a P type semiconductor region 103 (in a broad sense, a “first semiconductor region”), an N− type semiconductor region 104, a P+ type semiconductor region 105 (in a broad sense, a “second semiconductor region”), an N+ type semiconductor region 106 (in a broad sense, a “third semiconductor region”), a cathode contact 107 (in a broad sense, “second contact”), and an anode contact 108 (in a broad sense, “first contact”).

The photoelectric conversion region 102 is, for example, an N type well region, and photoelectrically converts incident light to generate an electron-hole pair (hereinafter, also referred to as a “charge”). The photoelectric conversion region 102 is provided in a region located closer to the back surface S2 of the semiconductor substrate 100 than the bottom of the first trench T1.

The P type semiconductor region 103 is, for example, a region including a P type (in a broad sense, a “first conductivity type”) acceptor, and is provided in a region surrounding the photoelectric conversion region 102 as illustrated in FIGS. 4 and 6. FIG. 4 illustrates a case where the P type semiconductor region 103 is provided on the back surface S2 side (upper side in FIG. 4) of the semiconductor substrate 100 with respect to the N+ type semiconductor region 106. Note that a region on the front surface S1 side (lower side in FIG. 4) of the semiconductor substrate 100 with respect to a front surface S4 (lower surface in FIG. 4) of the P type semiconductor region 103 is an N type well region 109 except for portions of the P+ type semiconductor region 105, the N+ type semiconductor region 106, and the cathode contact 107. The P type semiconductor region 103 forms an electric field guiding charges generated in the photoelectric conversion region 102 to the N− type semiconductor region 104 by applying the reverse bias voltage V_SPAD to the anode contact 108.

The N− type semiconductor region 104 is, for example, a region including a donor having a concentration higher than that of the photoelectric conversion region 102, and is provided in a central portion of the photoelectric conversion region 102 as illustrated in FIGS. 4 and 6. The N− type semiconductor region 104 takes in the charge generated in the photoelectric conversion region 102 and guides the charge to the P+ type semiconductor region 105. Note that the N− type semiconductor region 104 may be omitted.

The P+ type semiconductor region 105 is, for example, the same P type semiconductor region as the P type semiconductor region 103, is a region including a P type acceptor having a higher concentration than the P type semiconductor region 103, and is provided in a region in contact with the front surface S4 of the P type semiconductor region 103 (surface on the front surface S1 side of the semiconductor substrate 100). FIG. 4 illustrates a case where the P+ type semiconductor region 105 is provided in a region in contact with the front surface S4 of the P type semiconductor region 103, and a portion on a back surface S5 side (upper side in FIG. 4) of the P+ type semiconductor region 105 is buried in the P type semiconductor region 103. Furthermore, an area of the P+ type semiconductor region 105 is smaller than an area of the region surrounded by the first trench T1 such that the N type well region 109 is located between the P+ type semiconductor region 105 and the insulating film 111. Moreover, the area of the P+ type semiconductor region 105 is smaller than the area of the N+ type semiconductor region 106.

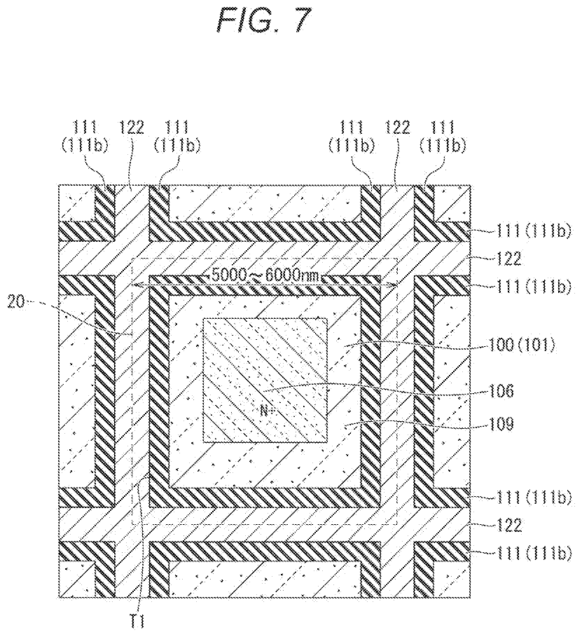

The N+ type semiconductor region 106 is, for example, an N type (in a broad sense, a “second conductivity type opposite to the first conductivity type”) semiconductor region, is a region including a donor having a concentration higher than that of the N− type semiconductor region 104, and is provided in a region in contact with a front surface S6 of the P+ type semiconductor region 105 (surface on the front surface S1 side of the semiconductor substrate 100). FIG. 4 illustrates a case where the N+ type semiconductor region 106 is provided in a region in contact with the front surface S6 of the P+ type semiconductor region 105, and a portion on a back surface S7 side (upper side in FIG. 4) of the N+ type semiconductor region 106 is in contact with the P+ type semiconductor region 105. Furthermore, as illustrated in FIG. 7, an area of the N+ type semiconductor region 106 is smaller than an area of the region surrounded by the first trench T1 such that the N type well region 109 is located between the N+ type semiconductor region 106 and the insulating film 111. Furthermore, the length in the width direction (left-right direction in FIG. 4) of the N type well region 109 sandwiched between the N+ type semiconductor region 106 and the insulating film 111 may be about several hundred nm or more. Then, the P+ type semiconductor region 105 and the N+ type semiconductor region 106 form a PN junction, and function as an amplification region 130 (see FIG. 5) that accelerates charges flowed in to generate an avalanche current. FIG. 7 is a view illustrating a cross-sectional configuration of the SPAD pixel 20 cut along line B-B in FIG. 4.

The cathode contact 107 is, for example, a region including a donor having a concentration higher than that of the N+ type semiconductor region 106, and is provided in a region in contact with the N+ type semiconductor region 106. FIG. 4 illustrates a case where the cathode contact 107 is provided on the front surface S1 of the semiconductor substrate 100, a portion on a back surface S8 side (upper side in FIG. 4) of the cathode contact 107 is in contact with the N+ type semiconductor region 106, and a portion on a front surface (surface opposite to the back surface S8 side. lower surface in FIG. 4) of the cathode contact 107 is exposed from the front surface S1 of the semiconductor substrate 100. The front surface (lower surface in FIG. 4) of the cathode contact 107 is in contact with the cathode electrode 121.

The anode contact 108 is, for example, a region including an acceptor having a concentration higher than that of the P+ type semiconductor region 105, and is provided in a region in contact with the P+ type semiconductor region 103. FIGS. 4 and 6 illustrate a case where the anode contact 108 is provided at the bottom of the first trench T1, the back surface (upper side in FIG. 4) and a side surface of the anode contact 108 are in contact with the P type semiconductor region 103, and a portion on the opposite side (lower side in FIG. 4) of the back surface is exposed from the bottom surface of the first trench T1. With such a structure, the formation position of the anode contact 108 is shifted in a height direction with respect to the formation position of the cathode contact 107 and the N+ type semiconductor region 106. A width of the anode contact 108 may be, for example, about 40 nm. Thus, by bringing the anode contact 108 into contact with the entire outer periphery of the P type semiconductor region 103, a uniform electric field can be formed in the photoelectric conversion region 102. The front surface (lower surface in FIG. 4) of the anode contact 108 is in contact with the anode electrode 122.

A wiring layer 120 is provided on the front surface S3 (lower surface in FIG. 4) of the insulating film 111. The wiring layer 120 includes an interlayer insulating film 123 and a wiring 124 provided in the interlayer insulating film 123. The wiring 124 is in contact with, for example, the cathode electrode 121 protruding from the front surface S3 of the insulating film 111. Note that, although omitted in the drawings, wiring in contact with the anode electrode 122 is also provided in the wiring layer 120. The circuit chip 72 is provided on a front surface S9 (lower surface in FIG. 4) of the wiring layer 120. With such a structure, the readout circuit 22 (see FIG. 3) and the like of the circuit chip 72 are electrically connected to the cathode electrode 121 via the wiring layer 120.

Further, a pinning layer 113 and a planarization film 114 are provided on the back surface S2 of the semiconductor substrate 100. Moreover, on a back surface S7 of the planarization film 114, a color filter 115 and an on-chip lens 116 are provided in this order for each SPAD pixel 20.

The pinning layer 113 is, for example, a fixed charge film including a hafnium oxide (HfO₂) film or an aluminum oxide (Al₂O₃) film containing a predetermined concentration of an acceptor. The planarization film 114 is, for example, an insulating film formed by an insulating material such as silicon oxide (SiO₂) or silicon nitride (SiN), and is a film for planarizing a surface on the color filter 115 side.

In the structure as described above, when the reverse bias voltage V_SPAD equal to or higher than a breakdown voltage is applied between the cathode contact 107 and the anode contact 108, an electric field for guiding the charge generated in the photoelectric conversion region 102 to the N− type semiconductor region 104 is formed by a potential difference between the P type semiconductor region 103 and the N+ type semiconductor region 106. In addition, in the PN junction region between the P+ type semiconductor region 105 and the N+ type semiconductor region 106, a high electric field region (amplification region 130) that generates the avalanche current by accelerating the entered charges is formed. Therefore, the operation of the photodiode 21 as the avalanche photodiode is realized.

Furthermore, by shifting the formation position of the anode contact 108 and the formation position of the cathode contact 107 and the N+ type semiconductor region 106 in the thickness direction of the semiconductor substrate 100, the distance from the anode contact 108 to the cathode contact 107 and the distance from the anode contact 108 to the N+ type semiconductor region 106 can be increased without increasing the size of the SPAD pixel 20 in the lateral direction (direction parallel to the front surface S1 of the semiconductor substrate 100). Therefore, the electric field between the anode contact 108, and the cathode contact 107 and the N+ type semiconductor region 106 is relaxed, and defects such as edge breakdown can be suppressed.

### 1-4 Configuration of Substantial Part

Next, a structure of the insulating film 111 is described in detail with reference to the drawings.

As illustrated in FIG. 5, the insulating film 111 includes a first region 111a and a second region 111b. FIG. 5 is an enlarged view illustrating a cross-sectional configuration of the photodiode 21 and the vicinity thereof.

The first region 111a is a region other than the second region 111b in the insulating film 111. FIG. 5 illustrates a case where the first region 111a is a region in the insulating film 111 including all of the portion whose depth from the front surface S1 of the semiconductor substrate 100 is shallower than a front surface S10 (lower surface in FIG. 4) and all of the portion where the depth is deeper than a back surface S11 (upper surface in FIG. 4) of the second region 111b. As a material of the first region 111a, for example, silicon oxide (SiO₂: relative dielectric constant 3.8 to 4.1) or silicon nitride (SiN: relative dielectric constant 7.0) can also be used. In particular, since a high reverse bias voltage is applied to the anode electrode 122, silicon oxide (SiO₂) is preferable from the viewpoint of withstand voltage performance.

The second region 111b is a region in the insulating film 111 including a portion whose depth from the front surface S1 of the semiconductor substrate 100 is located at a depth at which the distance L between the N+ type semiconductor region 106 and the anode electrode 122 is minimized. FIG. 4 illustrates a case where a region in the insulating film 111 located at the depth at which the N+ type semiconductor region 106 is provided is the second region 111b. As the material of the second region 111b, for example, a low dielectric constant material having a dielectric constant lower than that of the material of the first region 111a is used. Therefore, the dielectric constant ε2 of the second region 111b is lower than the dielectric constant ε1 of the first region 111a. The dielectric constant ε2 of the second region 111b is preferably 3.5 or less, more preferably 3.0 or less, still more preferably 2.8 or less in a case where the material of the first region 111a is silicon oxide (SiO₂). The lower limit value of the dielectric constant ε2 is preferably 2.3 or more.

As the low dielectric constant material, for example, hydrogen silsesquioxane resin (HSQ: relative dielectric constant of 3.0), benzocyclobutene (BCB: relative dielectric constant of 2.7), poly aryl ether (PAE: relative dielectric constant of 2.7), carbon-containing silicon oxide (SiOC: relative dielectric constant of 2.9), poly arylate (PAr: relative dielectric constant of 2.65), fluorine-doped silicon oxide (SiOF: relative dielectric constant of 2.6 to 3.7), and fluorine-doped silicon oxide (SiO₂ film fluorine-doped silicon dioxide: content of 11 at % and relative dielectric constant of 3.3 to 3.4) can also be used. In particular, fluorine-doped silicon oxide is preferable from the viewpoint of ease of production. The fluorine-doped silicon oxide is an oxide film to which fluorine is added, and is formed by, for example, a plasma chemical vapor deposition (CVD) method using a source such as a TEOS-C₂F₆ system or a tri ethoxy fluoro silane (TEFS).

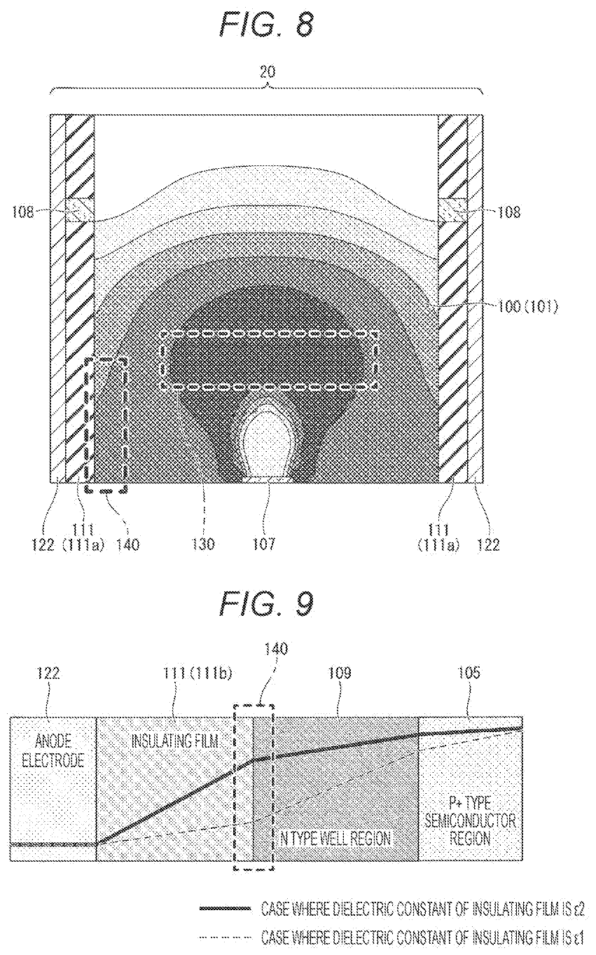

Here, the inventors of the present disclosure have found, from daily research, that the electric field of an interface 140 between the insulating film 111 and the semiconductor substrate 100 (N type well region 109) tends to be strong at the depth (hereinafter, also referred to as “first depth”) at which the distance L between the N+ type semiconductor region 106 and the anode electrode 122 is minimized in a case where the solid-state imaging device 10 is miniaturized as illustrated in FIG. 8. FIG. 8 is a view illustrating a result of a simulation in which an electric field intensity distribution of the semiconductor substrate 100 is analyzed in a case where an entire region of the insulating film 111 includes silicon oxide (SiO₂) as the first region 111a (that is, a region of a high dielectric constant) of the dielectric constant ε1. In FIG. 8, a region where the electric field is strong is represented in dark color, and a region where the electric field is weak is represented in light color. Note that the configuration of the SPAD pixel 20 is partially simplified for simulation in FIG. 8.

On the other hand, in the solid-state imaging device 10 according to the first embodiment, since the dielectric constant ε2 of the second region 111b of the insulating film 111 is lowered, as illustrated in FIG. 9, the potential gradient of the portion of the insulating film 111 located at the depth (first depth) at which the distance L between the N+ type semiconductor region 106 and the anode electrode 122 is minimized can be made steep, and accordingly, the potential gradient between the portion of the insulating film 111 located at the first depth and the N+ type semiconductor region 106 can be made gentle. Therefore, the electric field of the interface 140 where the electric field tends to be strong can be relaxed, and as a result, the electric field of the interface 140 between the insulating film 111 and the semiconductor substrate 100 (N type well region 109) can be relaxed.

Note that FIG. 9 is a diagram illustrating a potential state between the anode electrode 122 and the P+ type semiconductor region 105 at the first depth. In FIG. 9, a solid line indicates a potential state in the solid-state imaging device 10 according to the first embodiment. Furthermore, a broken line indicates a potential state in the solid-state imaging device 10 in which the insulating film 111 at the first depth is a region of the dielectric constant ε1 (a region of a high dielectric constant).

Therefore, according to the solid-state imaging device 10 according to the first embodiment, the edge breakdown caused by the electric field of the interface 140 can be suppressed by suppressing the electric field of the interface 140 between the insulating film 111 and the semiconductor substrate 100 (N type well region 109). Furthermore, the area of the amplification region 130 does not need to be reduced, and reduction in light detection efficiency can be suppressed. Therefore, two device requirements of (1) suppression of edge breakdown and (2) improvement of light detection efficiency can be simultaneously realized.

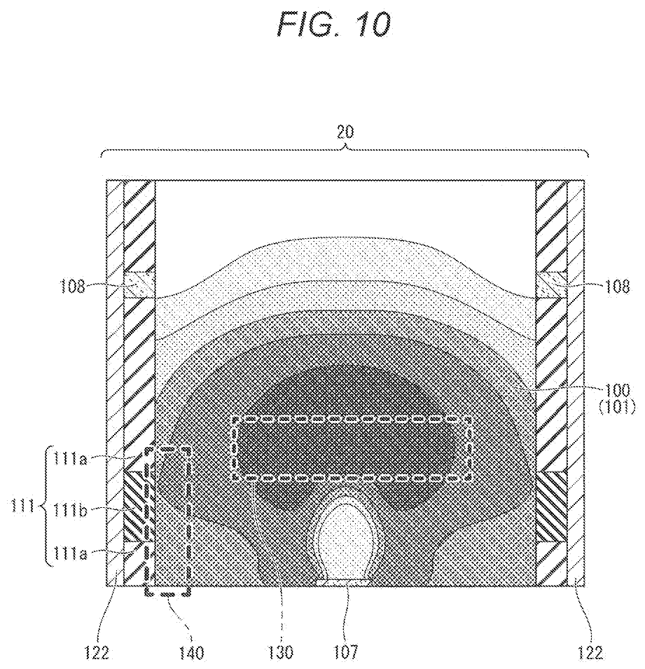

Furthermore, as illustrated in FIG. 10, it has been confirmed by simulation that the structure of the solid-state imaging device 10 according to the first embodiment, that is, the structure in which the dielectric constant ε2 of the portion of the insulating film 111 located at the depth (first depth) at which the distance L between the N+ type semiconductor region 106 and the anode electrode 122 is minimized is reduced, enables suppression of the electric field at the interface 140 without reducing the area of the amplification region 130. FIG. 10 is a view illustrating a result of a simulation in which an electric field intensity distribution of the semiconductor substrate 100 is analyzed in the solid-state imaging device 10 according to the first embodiment. Note that the configuration of the SPAD pixel 20 is partially simplified for simulation in FIG. 10.

### 1-5 Manufacturing Method

Next, a manufacturing method for the solid-state imaging device 10 according to the first embodiment will be described in detail with reference to the drawings. Note that in the following description, a manufacturing method for the light receiving chip 71 will be focused.

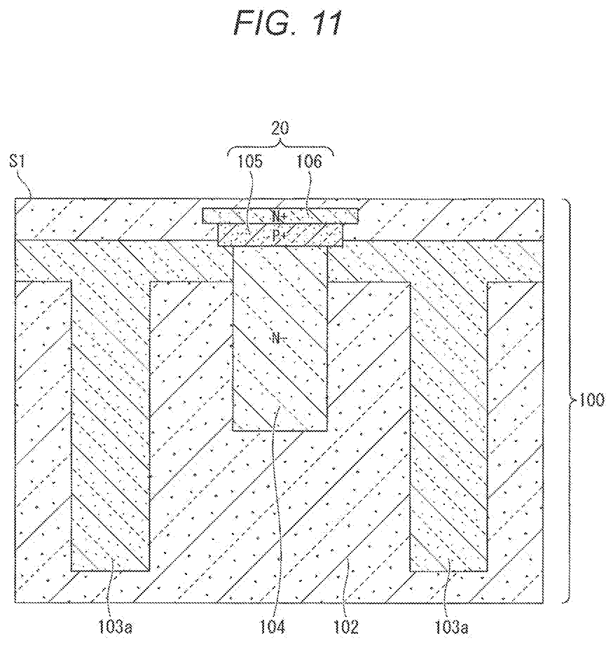

FIGS. 11 to 23 are process cross-sectional views illustrating the manufacturing method for the solid-state imaging device 10.

First, as illustrated in FIG. 11, a part (hereinafter, also referred to as a “P type semiconductor region 103a”) of the P type semiconductor region 103 that partitions the photoelectric conversion region 102, the N− type semiconductor region 104, the P+ type semiconductor region 105, the N+ type semiconductor region 106, and the N type well region 109 are formed by appropriately ion-implanting a donor and an acceptor into a predetermined region in the semiconductor substrate 100 including a donor having a low concentration as a whole. Note that the ion implantation may be performed, for example, from the front surface S1 of the semiconductor substrate 100. Furthermore, after the ion implantation, annealing for recovery of damage during the ion implantation and improvement of the profile of the implanted dopant may be performed.

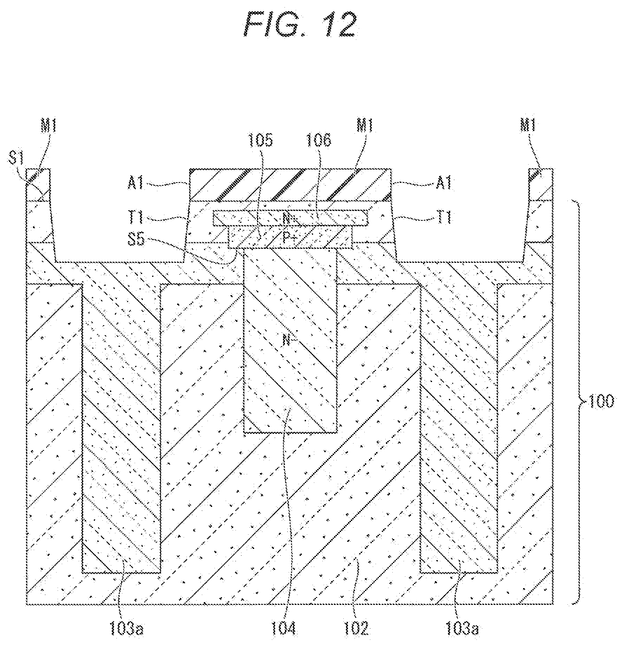

Next, as illustrated in FIG. 12, a mask M1 having a lattice-shaped opening A1 is formed on the front surface S1 of the semiconductor substrate 100, and the semiconductor substrate 100 is carved by anisotropic dry etching such as reactive ion etching (RIE) using the mask M1. As a result, the lattice-shaped first trench T1 is formed along the boundary portions of the adjacent SPAD pixels 20. The depth of the first trench T1 is a depth at which the bottom surface of the first trench T1 is located at a level deeper than at least the back surface S5 (lower surface in FIG. 12) of the P+ type semiconductor region 105 and reaches the P type semiconductor region 103a.

Note that, as the depth of the first trench T1 from the front surface S1 of the semiconductor substrate 100 is deeper, the distance from the anode contact 108 to the N+ type semiconductor region 106 and the cathode contact 107 can be secured as illustrated in FIG. 4. However, if the first trench T1 is made too deep, there is a possibility that process accuracy deteriorates and a yield decreases. Therefore, the depth of the first trench T1 is preferably set within a range in which necessary process accuracy can be secured.

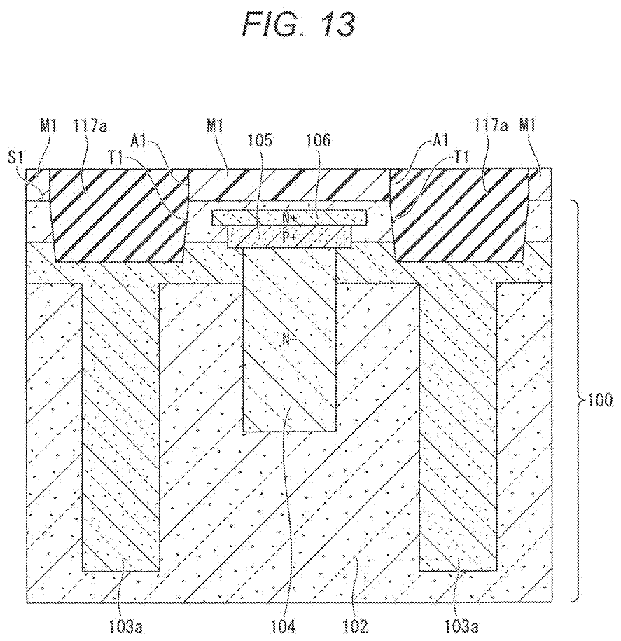

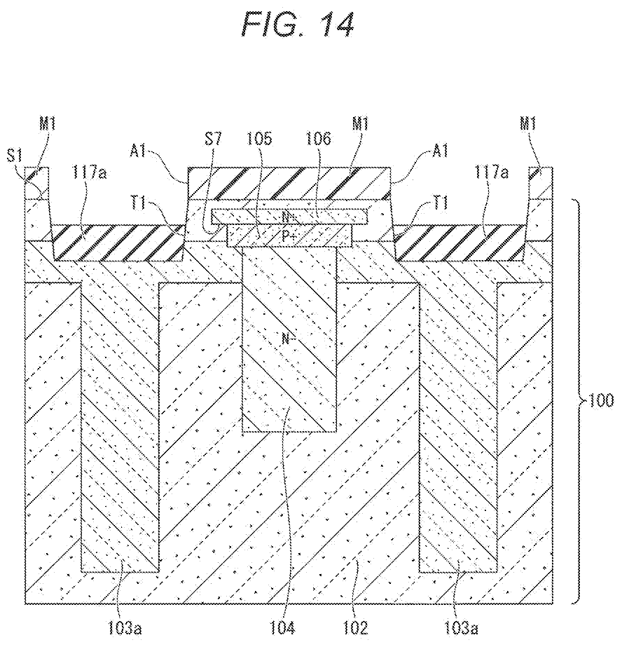

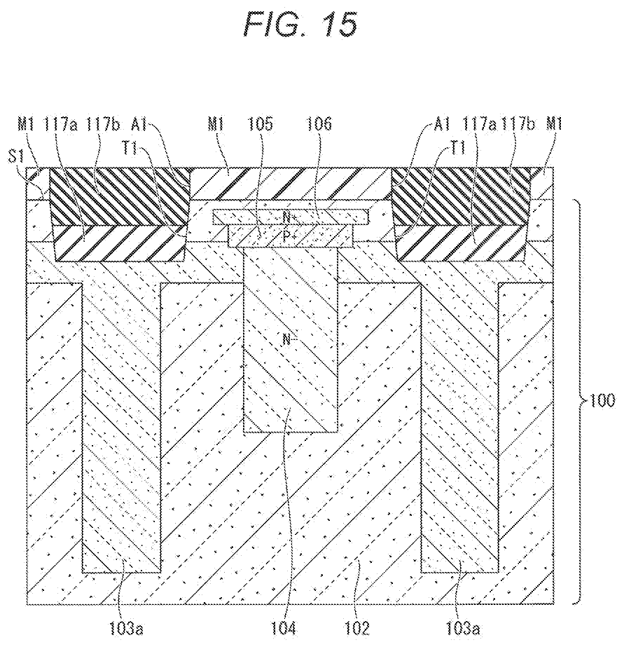

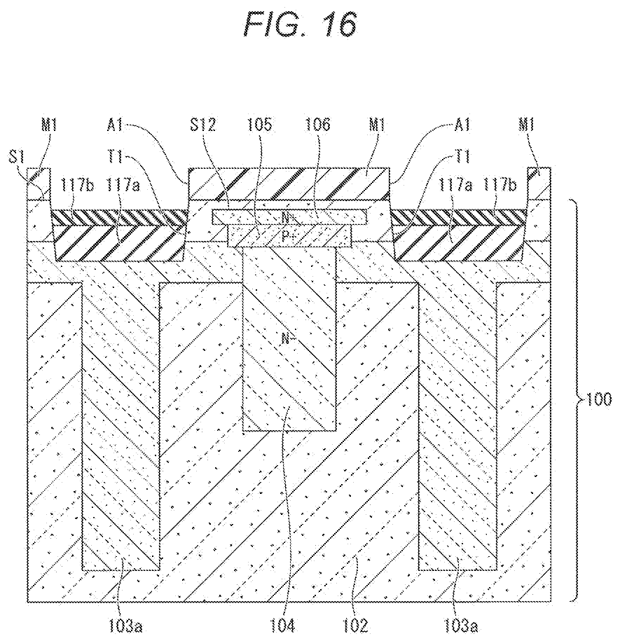

Next, as illustrated in FIG. 13, a first insulating film 117a is embedded in the first trench T1 by using, for example, a film forming technique such as sputtering or a chemical vapor deposition (CVD) method. As a material of the first insulating film 117a, the same material as the first region 111a of the insulating film 111 is used. Next, as illustrated in FIG. 14, the first insulating film 117a is removed to a predetermined depth by using anisotropic dry etching such as RIE. FIG. 14 illustrates a case where the first insulating film 117a is removed to the same depth as the back surface S7 (lower surface in FIG. 14) of the N+ type semiconductor region 106. Next, as illustrated in FIG. 15, a second insulating film 117b is embedded in the first trench T1 by using, for example, a film forming technique such as sputtering or a CVD method. As a material of the second insulating film 117b, the same material as the second region 111b of the insulating film 111 is used. Next, as illustrated in FIG. 16, the second insulating film 117b is removed to a predetermined depth by using anisotropic dry etching such as RIE. FIG. 16 illustrates a case where the second insulating film 117b is removed to the same depth as a front surface S12 (upper surface in FIG. 16) of the N+ type semiconductor region 106. Therefore, the second insulating film 117b is provided at the same depth as the N+ type semiconductor region 106.

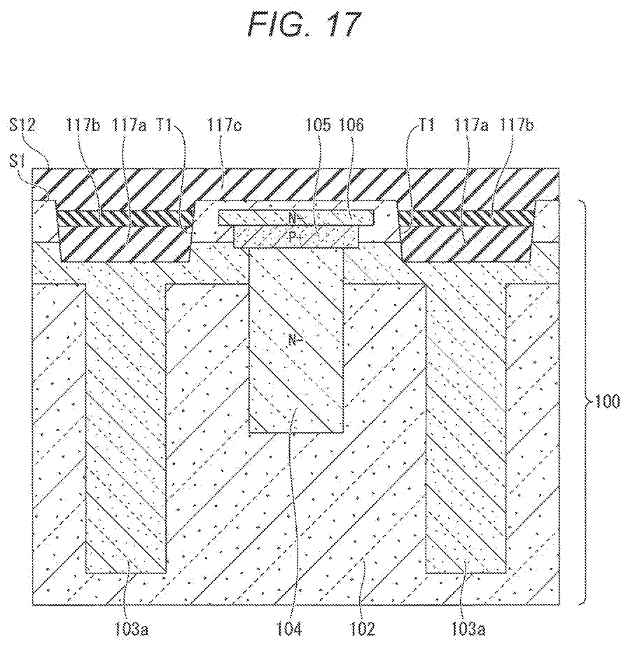

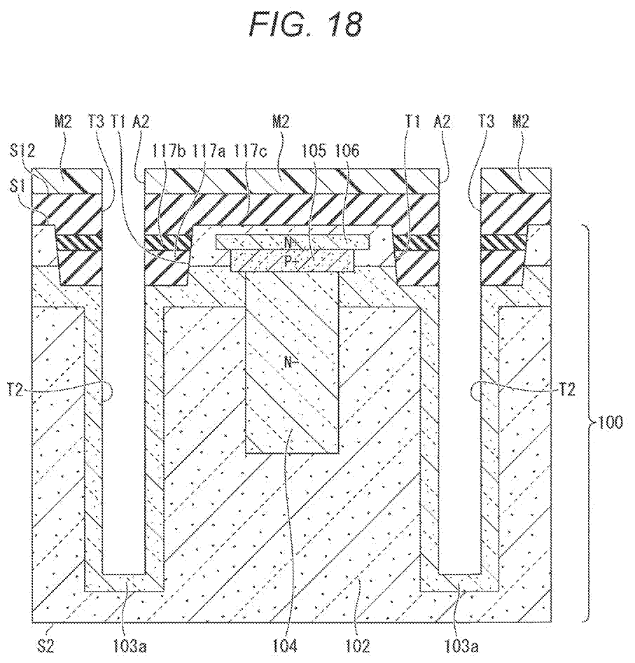

Next, as illustrated in FIG. 17, after the mask M1 is removed, a third insulating film 117c covering the front surface S1 of the semiconductor substrate 100 and embedded inside the first trench T1 is formed by using, for example, a film forming technique such as sputtering or a CVD method. Therefore, the front surface S12 (upper surface in FIG. 18) of the third insulating film 117c is formed as a flat surface without unevenness. Next, as illustrated in FIG. 18, a mask M2 having a lattice-shaped opening A2 is formed on the front surface S12 of the third insulating film 117c, and the third insulating film 117c, the second insulating film 117b, the first insulating film 117a, and the semiconductor substrate 100 in the first trench T1 are carved by anisotropic dry etching such as RIE from above the mask M2. As a result, a trench T3 reaching from the front surface S1 side to the vicinity of the back surface S2 (lower surface in FIG. 18) of the semiconductor substrate 100 is formed from the front surface S12 of the third insulating film 117c. A portion of the trench T3 reaching from the bottom of the first trench T1 to the vicinity of the back surface S2 of the semiconductor substrate 100 constitutes the second trench T2 of the element isolation portion 110 illustrated in FIG. 4.

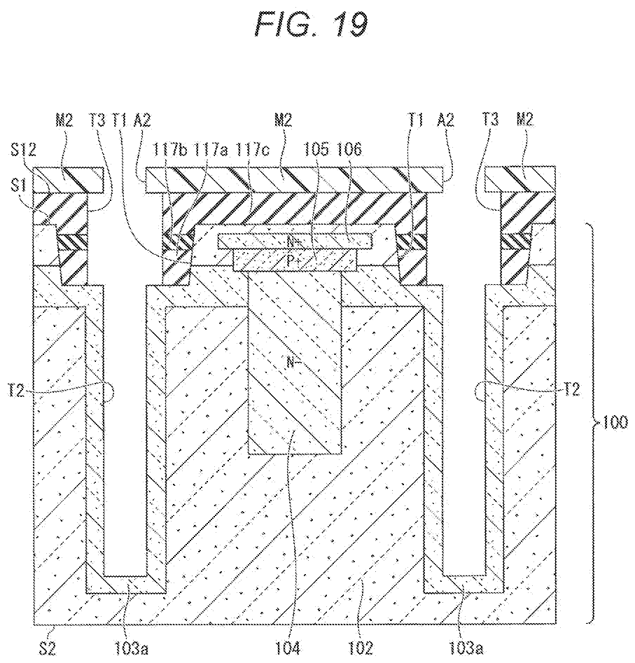

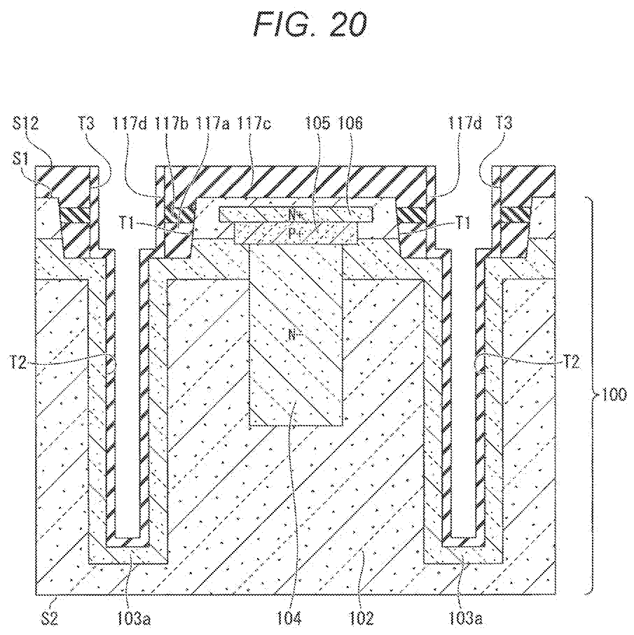

Next, as illustrated in FIG. 19, the first insulating film 117a, the second insulating film 117b, and the third insulating film 117c in the first trench T1 are retracted by isotropic etching such as wet etching, so that an upper portion of the P type semiconductor region 103a is exposed at the bottom of the first trench T1. Next, as illustrated in FIG. 20, after the mask M2 is removed, a fourth insulating film 117d covering an inner side surface of the trench T3 (including the second trench T2) is formed by using, for example, a film forming technique such as a CVD method. As a material of the fourth insulating film 117d, the same material as the first Insulating film 117a is used.

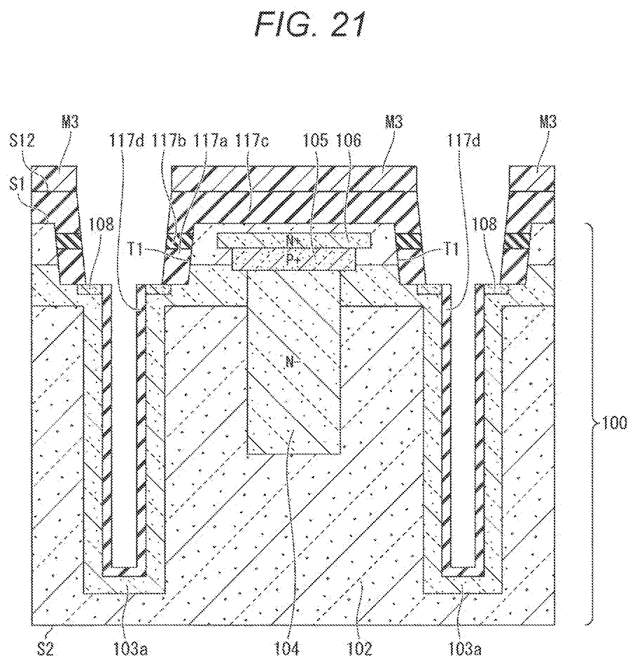

Next, as illustrated in FIG. 21, a mask M3 having a lattice-shaped opening A3 is formed on the front surface S12 of the third insulating film 117c, and anisotropic dry etching such as RIE is used from above the mask M3 to remove the fourth insulating film 117d covering the inner side surface of the trench T3 to the bottom of the first trench T1. Therefore, the insulating film 111 having the first region 111a and the second region 111b is completed by the first insulating film 117a, the second insulating film 117b, the third insulating film 117c, and the fourth insulating film 117d. Moreover, an acceptor is ion-implanted at a high concentration from above the mask M3. Therefore, the anode contact 108 including a high-concentration acceptor is provided at the bottom of the first trench T1, that is, in an upper portion of the P type semiconductor region 103 (see FIG. 6).

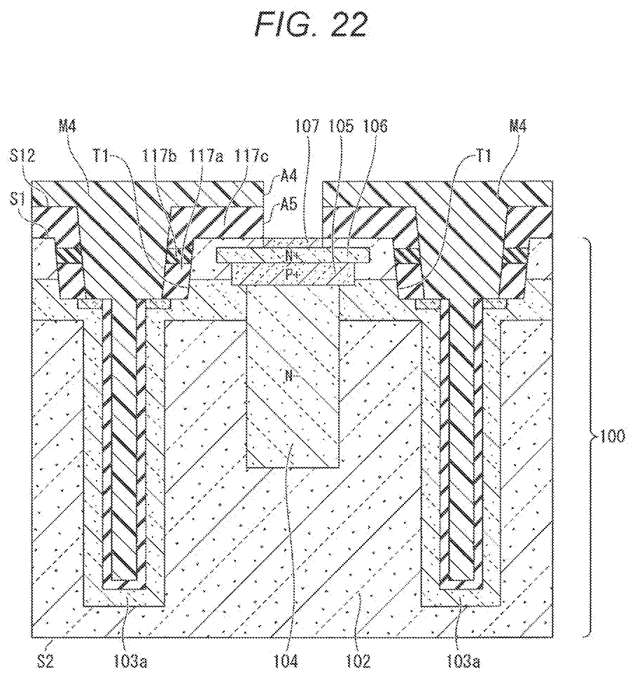

Next, as illustrated in FIG. 22, after the mask M3 is removed, a mask M4 having an opening A4 above the N+ type semiconductor region 106 is formed on the front surface S12 of the third insulating film 117c, and the third insulating film 117c is carved from above the mask M4 by anisotropic dry etching such as RIE to form an opening A5 that exposes the front surface S1 of the semiconductor substrate 100. Moreover, a donor is ion-implanted at a high concentration from above the mask M4. Therefore, the cathode contact 107 containing a high-concentration donor is provided in a part of the semiconductor substrate 100 located on the N+ type semiconductor region 106. Note that the method of forming the anode contact 108 and the cathode contact 107 is not limited to the ion implantation method, and solid-phase diffusion, plasma doping, or the like can also be adopted.

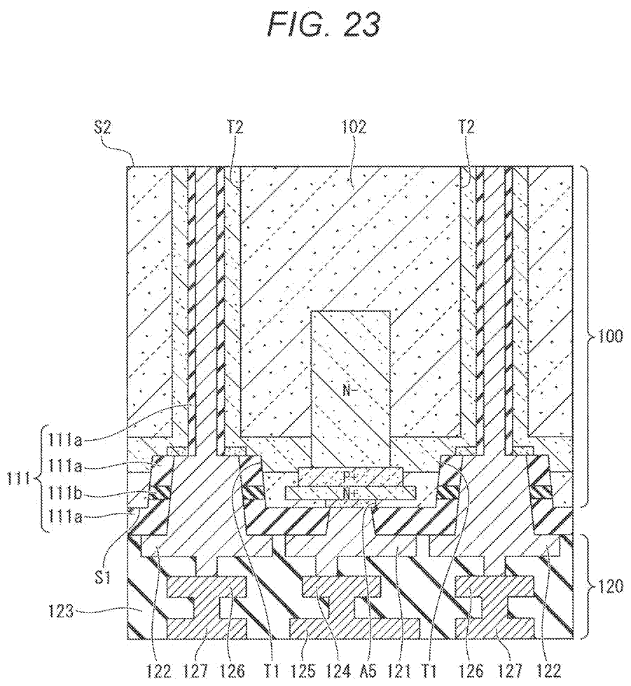

Next, as illustrated in FIG. 23, after the mask M4 is removed, by using, for example, a lift-off method or the like, the light shielding film 112 is formed in the second trench T2, the anode electrode 122 in contact with the anode contact 108 is formed in the first trench T1, and the cathode electrode 121 in contact with the cathode contact 107 is further formed in the opening A5. As materials of the light shielding film 112, the cathode electrode 121, and the anode electrode 122, in addition to tungsten (W), various conductive materials having a property of reflecting or absorbing visible light or light necessary for each element, such as aluminum (Al), an aluminum alloy, or copper (Cu), can be adopted as described above.

Next, the wiring layer 120 including the wiring 124 connected to the cathode electrode 121, a wiring 126 connected to the anode electrode 122, and the interlayer insulating film 123 is formed on the insulating film 111 provided with the cathode electrode 121 and the anode electrode 122. Furthermore, connection pads 125 and 127 including copper (Cu) exposed on a front surface of the interlayer insulating film 123 are formed. Next, by thinning the semiconductor substrate 100 from the back surface S2, the light shielding film 112 in the second trench T2 penetrates the second trench T2 so as to reach the back surface S2 of the semiconductor substrate 100. For example, chemical mechanical polishing (CMP) or the like can be adopted for thinning the semiconductor substrate 100.

Next, an acceptor is ion-implanted into the entire back surface S2 of the semiconductor substrate 100. Therefore, the P type semiconductor region 103 surrounding the photoelectric conversion region 102 is completed. Thereafter, by sequentially forming the pinning layer 113, the planarization film 114, the color filter 115, and the on-chip lens 116 on the back surface S2 of the semiconductor substrate 100, the light receiving chip 71 in the solid-state imaging device 10 is provided. Then, by bonding the separately prepared circuit chip 72 and light receiving chip 71 to each other, the solid-state imaging device 10 having the cross-sectional structure illustrated in FIG. 4 is manufactured.

### 1-6 Modifications

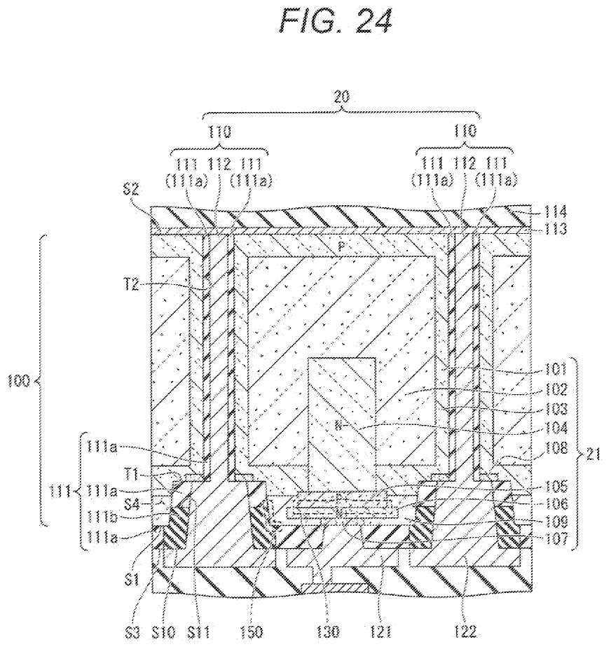

(1) In the first embodiment, an example in which a region in the insulating film 111 including a portion located at the depth (first depth) at which the distance between the N+ type semiconductor region 106 and the anode electrode 122 is minimized is the second region 111b (low dielectric constant region) has been described, but other configurations can also be adopted. For example, as illustrated in FIG. 24, the second region 111b may include a portion (portion on the front surface S1 side of the semiconductor substrate 100) of the insulating film 111 whose depth from the front surface S1 of the semiconductor substrate 100 is shallower than the depth (first depth) at which the distance between the N+ type semiconductor region 106 and the anode electrode 122 is minimized. FIG. 24 illustrates a case where a region in the insulating film 111 including all of a shallow portion at a depth equal to or less than the first depth and in contact with the anode electrode 122 is the second region 111b. Furthermore, in FIG. 24, the deepest portion of the second region 111b is located at a depth at which the interface between the P+ type semiconductor region 105 and the N+ type semiconductor region 106 is located.

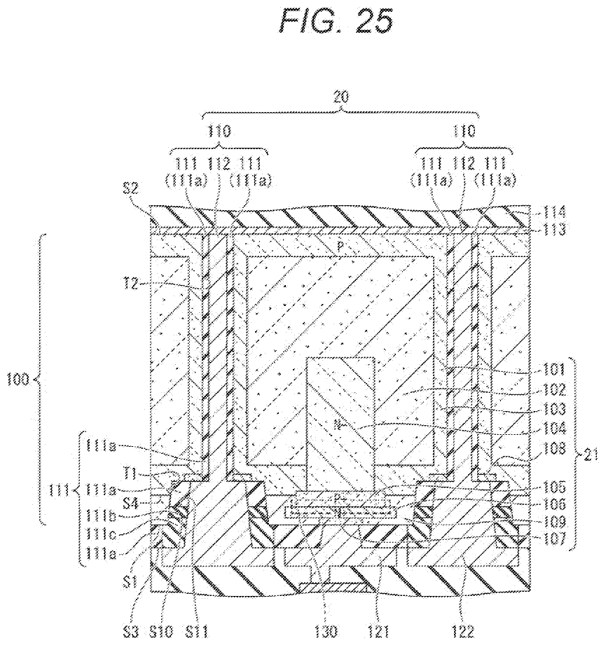

Here, the inventors of the present disclosure have found, from daily research, that the electric field of an interface 150 between the insulating film 111 and the semiconductor substrate 100 tends to be strong even at the portion (hereinafter, also referred to as “second depth”) shallower than the depth (first depth) at which the distance between the N+ type semiconductor region 106 and the anode electrode 122 is minimized due to the potential of a hammer portion (portion extending on the front surface S3 of the insulating film 111) of the anode electrode 122 having a hammerhead shape. On the other hand, in the present modification, the dielectric constant of a portion (hereinafter also referred to as “second portion”) located at the second depth of the insulating film 111 is also lowered. Therefore, the potential gradient between the second portion and the N+ type semiconductor region 106 can be made gentle. Therefore, the electric field (interface at which the electric field tends to be strong) at the interface 150 between the second portion and the semiconductor substrate 100 can be relaxed, and the occurrence of edge breakdown can be suppressed.
(2) Furthermore, for example, as illustrated in FIG. 25, the insulating film 111 may have a third region 111c in addition to the first region 111a and the second region 111b. The third region 111c is a region in the insulating film 111 located in a portion shallower than the second region 111b. FIG. 25 illustrates a case where a region in the insulating film 111 including all of a shallow portion at a depth shallower than the front surface S10 (surface on the front surface S1 side of the semiconductor substrate 100) of the second region 111b and in contact with the anode electrode 122 is the third region 111c. A dielectric constant ε3 of the third region 111c is lower than the dielectric constant ε1 of the first region 111a and higher than the dielectric constant ε2 of the second region 111b (ε2<ε3<ε1). With such a structure, the dielectric constant ε3 of the portion (second portion) located at the shallow portion of the insulating film 111 is lowered (ε3<ε1) similarly to the modification (1), and thus the electric field at the interface between the second portion and the semiconductor substrate 100 can be relaxed.

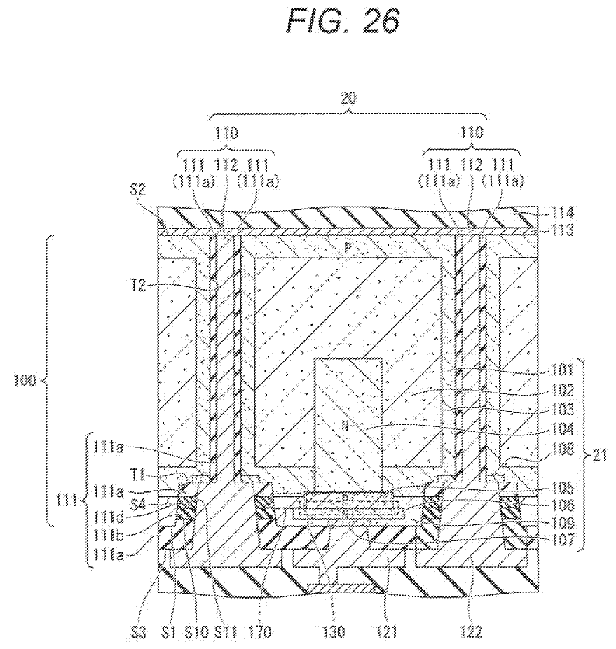

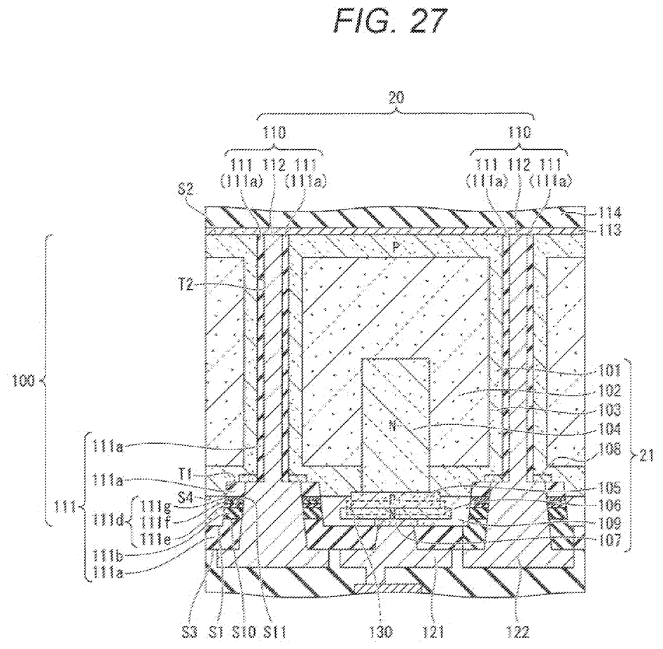

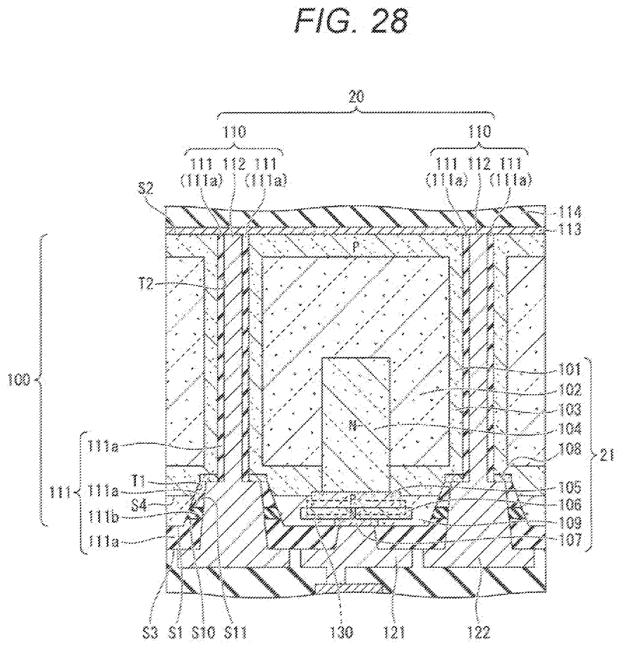

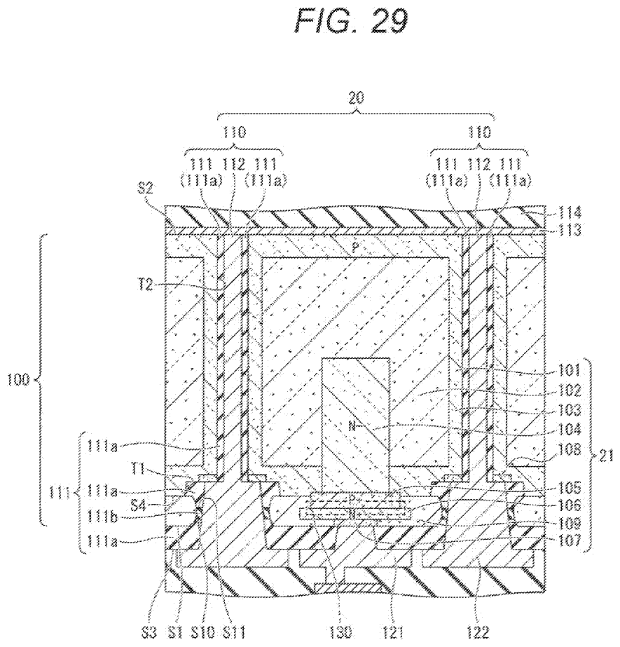

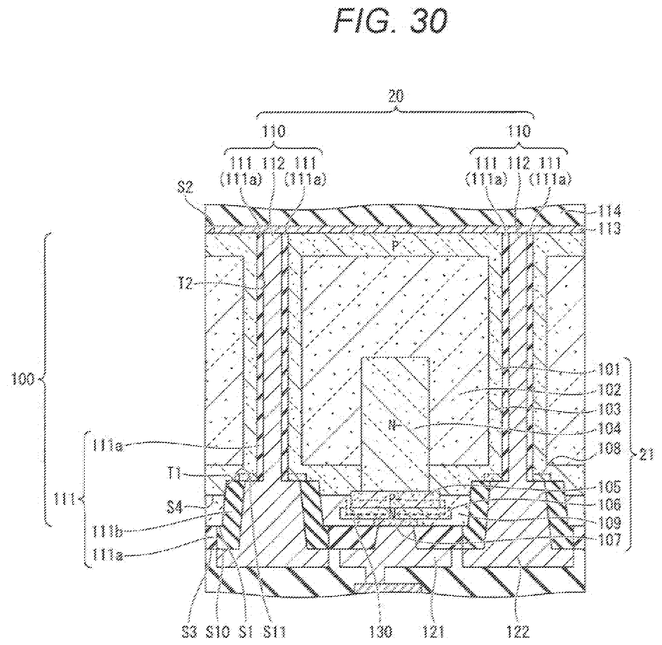

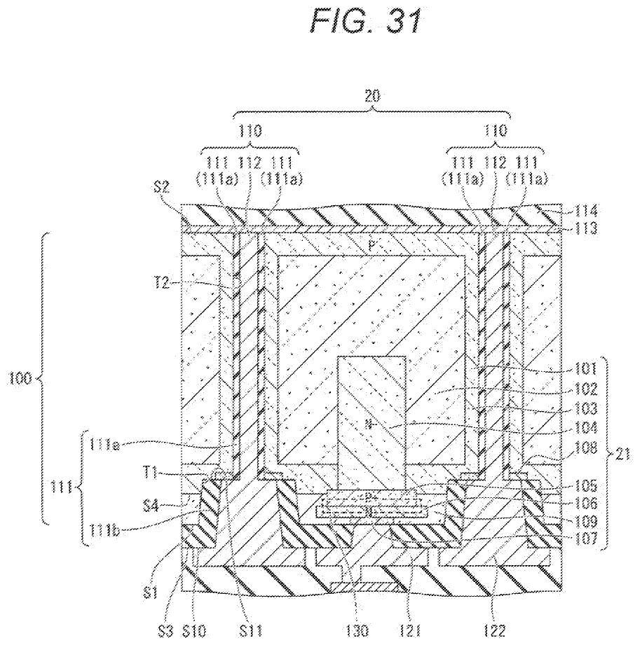

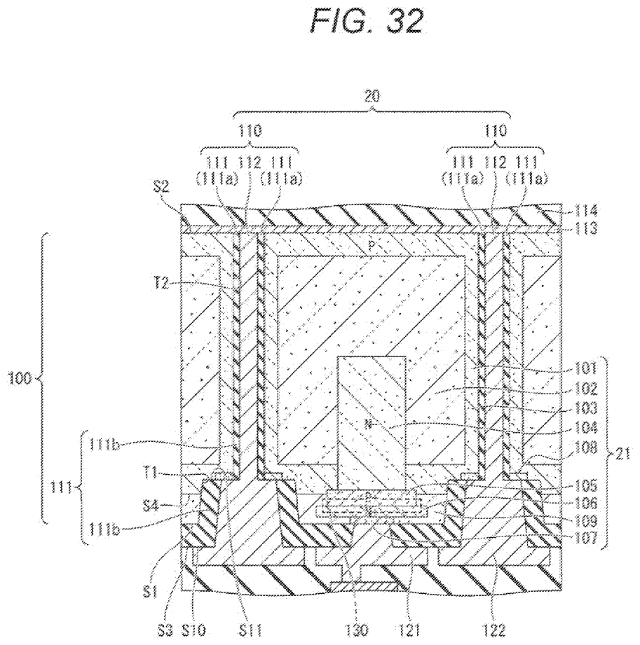

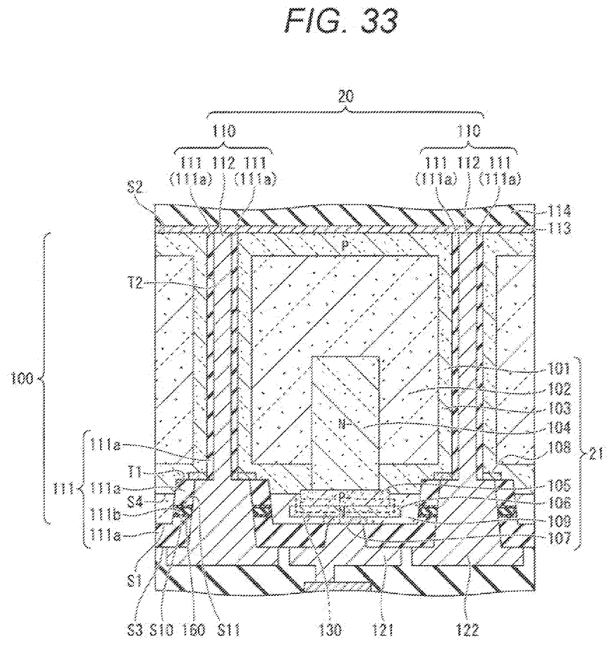

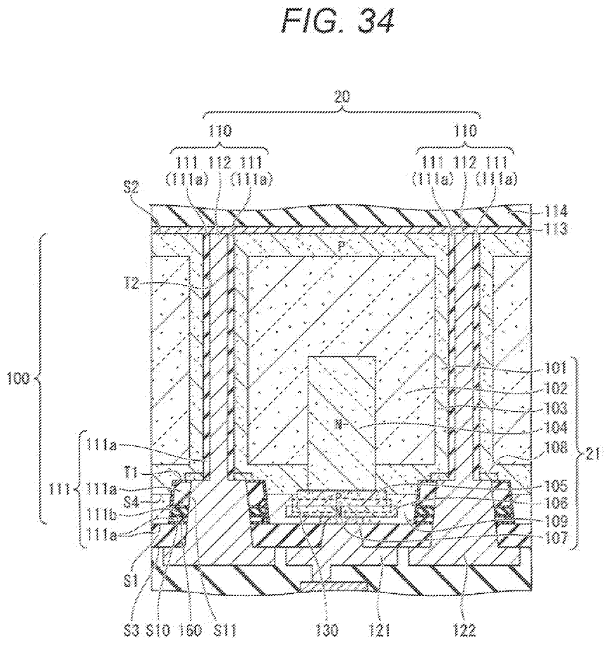

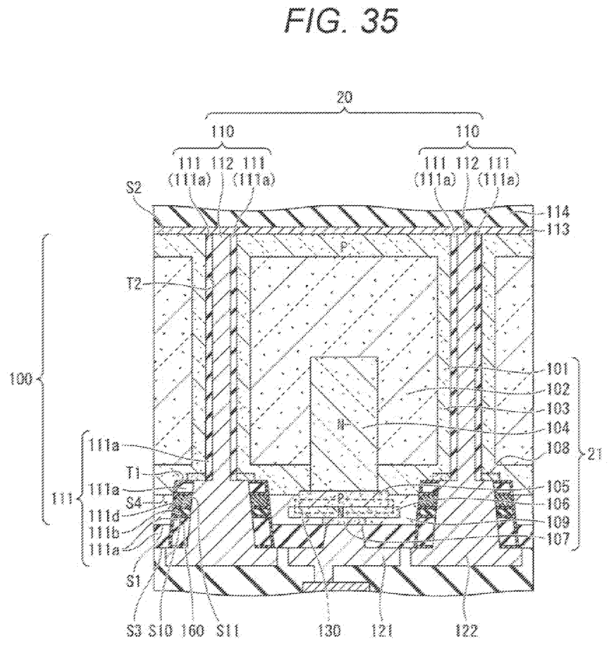

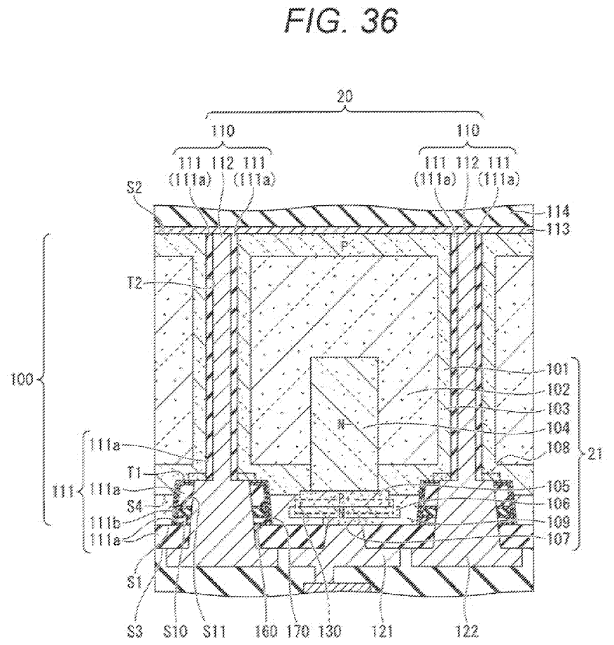

Here, for example, in a case where the first region 111a is formed in the second portion, in the semiconductor substrate 100, an electric field is generated in the thickness direction of the semiconductor substrate 100 due to a potential difference between a portion located at the depth of the second region 111b and a portion located at the depth of the first region 111a. On the other hand, in the present modification, since the dielectric constant ε3 of the third region 111c provided in the second portion is higher than the dielectric constant ε2 of the second region 111b, the electric field generated in the thickness direction of the semiconductor substrate 100 can be suppressed.
(3) Furthermore, for example, as illustrated in FIG. 26, the insulating film 111 may have a fourth region 111d in addition to the first region 111a and the second region 111b. The fourth region 111d is a region in the insulating film 111 located in a portion deeper than the second region 111b. FIG. 26 illustrates a case where a portion of the insulating film 111 from the back surface S11 (surface on the back surface S2 side of the semiconductor substrate 100) of the second region 111b to the depth at which the front surface S4 (surface on the front surface S1 side of the semiconductor substrate 100) of the P type semiconductor region 103 is located is the fourth region 111d. That is, in FIG. 26, the fourth region 111d is located at the depth at which the P+ type semiconductor region 105 is provided. A dielectric constant ε4 of the fourth region 111d is higher than the dielectric constant ε1 of the first region 111a and the dielectric constant ε2 of the second region 111b (ε2<ε1<ε4). With such a structure, the potential on the fourth region 111d side (the left side or the right side of the P+ type semiconductor region 105 in FIG. 26) of the P+ type semiconductor region 105 can be controlled to increase the area of the amplification region 130 (high electric field region), and the light detection efficiency can be improved. Note that FIG. 26 illustrates a case where the first region 111a is the entire region in the insulating film 111 other than the second region 111b and the third region 111c. Furthermore, as a material of the fourth region 111d, for example, silicon nitride (SiN) can be used in a case where the material of the first region 111a is silicon oxide (SiO₂).
(4) Furthermore, for example, as illustrated in FIG. 27, the fourth region 111d of the modification (3) may be divided into a plurality of regions in the depth direction from the front surface S1 of the semiconductor substrate 100. FIG. 27 illustrates a case where the fourth region 111d is divided into three regions arranged from the side closer to the front surface S1 of the semiconductor substrate 100, that is, a fifth region 111e, a sixth region 111f, and a seventh region 111g. Furthermore, dielectric constants ε5, ε6, and ε7 of the plurality of regions 111e, 111f, and 111g, respectively, are higher in a region deeper from the front surface of the semiconductor substrate 100 (ε2<ε1<ε5<ε6<ε7). Here, ε5 is the dielectric constant of the fifth region 111e, ε6 is the dielectric constant of the sixth region 111f, and ε7 is the dielectric constant of the seventh region 111g. With such a structure, the electric field generated in the thickness direction of the semiconductor substrate 100 can be suppressed, the potential on the fourth region 111d side of the P+ type semiconductor region 105 can be controlled more appropriately, the area of the amplification region 130 (high electric field region) can be increased, and the light detection efficiency can be improved.
(5) Furthermore, in the first embodiment, the example in which the film thickness of the portion of the insulating film 111 covering the inner side surface of the first trench T1 is constant has been described, but other configurations can also be adopted. For example, as illustrated in FIG. 28, the film thickness of the portion of the insulating film 111 covering the inner side surface of the first trench T1 may be thinner toward the bottom of the first trench T1. With such a structure, the distance between the second region 111b of the insulating film 111 and the N+ type semiconductor region 106 can be increased, and accordingly, the potential gradient between the second region 111b and the N+ type semiconductor region 106 can be made gentle. Therefore, the electric field at the interface between the second region 111b and the semiconductor substrate 100 can be further relaxed. Note that in the case of such a structure, as the material of the second region 111b, for example, a material having a lower dielectric constant than that in the case where the film thickness of the insulating film 111 is constant may be used.
(6) Furthermore, for example, as illustrated in FIG. 29, in at least a part of the portion of the insulating film 111 covering the inner side surface of the first trench T1, the film thickness may decrease as the depth from the front surface S1 of the semiconductor substrate 100 is closer to the depth at which the second region 111b is provided. FIG. 29 illustrates a case where a region including all of the portion of the insulating film 111 where the depth from the front surface S1 of the semiconductor substrate 100 is shallower than the front surface S4 of the P type semiconductor region 103 and deeper than the front surface S1 of the semiconductor substrate 100 is a region having a small film thickness. Therefore, the distance between the second region 111b of the insulating film 111 and the N+ type semiconductor region 106 can be increased, and accordingly, the potential gradient between the second region 111b and the N+ type semiconductor region 106 can be made gentle. Therefore, the electric field at the interface between the second region 111b and the semiconductor substrate 100 can be further relaxed. Note that in the case where such a structure is adopted, as the material of the second region 111b, for example, a material having a much lower dielectric constant than that in the case where the film thickness of the insulating film 111 is constant may be used.
(7) Furthermore, for example, as illustrated in FIGS. 30, 31, and 32, the second region 111b may be a region in the insulating film 111 located in a portion whose depth from the front surface S1 of the semiconductor substrate 100 is shallower than the bottom surface of the first trench T1. With such a structure, the structure of the insulating film 111 can be simplified, the process can be simplified, and ease of manufacturing the solid-state imaging device 10 can be improved. FIG. 30 illustrates a case where a region including all of the portion of the insulating film 111 at the depth shallower than the bottom surface of the first trench T1 and in contact with the anode electrode 122 is the second region 111b. Furthermore, FIG. 31 illustrates a case where, in addition to the portion illustrated in FIG. 30, all of the portion of the insulating film 111 covering the front surface S1 of the semiconductor substrate 100 is the second region 111b. Furthermore, FIG. 32 illustrates a case where the entire insulating film 111 is the second region 111b (that is, a region formed using a low dielectric constant material having a relative dielectric constant of 3.5 or less). Here, the structure illustrated in FIG. 32 is also an example of a case where the portion of the insulating film 111 whose depth from the front surface S1 of the semiconductor substrate 100 is located at a depth at which the distance between the N+ type semiconductor region 106 and the anode electrode 122 is minimized is formed using a low dielectric constant material having a relative dielectric constant of 3.5 or less.
(8) Furthermore, for example, as illustrated in FIGS. 33, 34, and 35, the front surface S10 and the back surface S11 (the surface on the front surface S1 side of the semiconductor substrate 100 and the surface on the other side) of the second region 111b may be covered with a protective film 160. Therefore, for example, in a case where the second region 111b includes fluorine-doped silicon oxide, fluorine in the second region 111b can be prevented from diffusing into the first region 111a. FIG. 33 illustrates a case where the protective film 160 is formed on the front surface S10, the back surface S11, and the side surface (the surface on the inner side surface side of the first trench T1) of the second region 111b. FIG. 34 illustrates a case where the protective film 160 is formed on other surfaces and the like in addition to the front surface S10 and the back surface S11 of the second region 111b. Note that FIG. 35 illustrates a case where the present modification is applied to the SPAD pixel 20 (see FIG. 26) of Modification (3). As a material of the protective film 160, for example, a material different from the material of the insulating film 111, such as silicon nitride (SiN), can be used.
(9) Furthermore, for example, as illustrated in FIG. 36, in a case where the protective film 160 is formed, a base film 170 may be formed between the protective film 160 and the semiconductor substrate 100. Here, for example, when a silicon nitride film (protective film 160) is directly formed on silicon (semiconductor substrate 100), there is a possibility that stress is generated at the interface to cause damage such as distortion to a crystal. On the other hand, in the present modification, since the base film 170 is provided, damage to the crystal can be suppressed. FIG. 36 illustrates a case where the present modification is applied to the SPAD pixel 20 illustrated in FIG. 34 of Modification (8), and the base film 170 is formed between the protective film 160, and the inner side surface and the bottom surface of the first trench T1. As a material of the base film 170, for example, silicon oxide (SiO₂) or the like can be used.
(10) Furthermore, in the first embodiment, the case where the first conductivity type is the P type and the second conductivity type is the N type has been exemplified, but other configurations can also be adopted. For example, the first conductivity type may be the N type, and the second conductivity type may be the P type. In this case, the SPAD pixel 20 has a structure in which the “P type semiconductor region 103” is an N type semiconductor region, the “N− type semiconductor region 104” is a P− type semiconductor region, the “P+ type semiconductor region 105” is an N+ type semiconductor region, and the “N+ type semiconductor region 106” is a P+ type semiconductor region in the SPAD pixel 20 illustrated in FIG. 4. Furthermore, the “cathode contact 107” is an anode contact, and the “anode contact 108” is a cathode contact. Note that the “N type well region 109” may be a P type semiconductor region, an N type semiconductor region, or a non-doped semiconductor region. As described above, the first embodiment or the modifications thereof can be applied to the SPAD pixel 20 in which the first conductivity type is the N type and the second conductivity type is the P type, and the description in the case of application is similar to the first embodiment or the modifications (1) to (9) thereof described above, so the detailed description thereof is herein omitted.
(11) Furthermore, although the example in which the present technology is applied to an imaging device is described in the first embodiment, other configurations can also be employed. For example, the present invention may be applied to a distance measuring device that measures a distance to an object. FIG. 37 is a view illustrating a cross-sectional configuration of the solid-state imaging device 10 according to the present modification. As illustrated in FIG. 37, the SPAD pixel 20 of the present modification has a structure in which the color filter 115 is omitted from the structure illustrated in FIG. 4. Other configurations, operations, and effects may be similar to those of the first embodiment or the modifications (1) to (10) thereof described above, so the detailed description is herein omitted.

Note that, the present technology may also have the following configuration.
(1)

A light detection device including:
a semiconductor substrate;
a first trench having a lattice shape and provided on a first surface of the semiconductor substrate;
a second trench having a lattice shape, provided at a bottom of the first trench and extending along the bottom;
an insulating film covering each of inner side surfaces of the first and second trenches and the first surface;
a photoelectric conversion region provided in an element region obtained by partitioning the semiconductor substrate by the first and second trenches, the photoelectric conversion region photoelectrically converting incident light to generate a charge;
a first semiconductor region provided in the element region and surrounding the photoelectric conversion region;
a first contact provided at the bottom of the first trench and in contact with the first semiconductor region;
a first electrode disposed in the first trench and in contact with the first contact;
a second semiconductor region provided in a region in contact with a surface of the first semiconductor region on the first surface side in the element region and having a first conductivity type same as a conductivity type of the first semiconductor region;
a third semiconductor region provided in a region in contact with a surface of the second semiconductor region on the first surface side in the element region and having a second conductivity type opposite to the first conductivity type;
a second contact provided on the first surface and in contact with the third semiconductor region; and
a second electrode in contact with the second contact, in which
the insulating film includes at least a first region and a second region, the second region is a region including a portion whose depth from the first surface is located at a depth at which a distance between the third semiconductor region and the first electrode is minimized, and a dielectric constant of the second region is lower than a dielectric constant of the first region.
(2)

The light detection device according to (1), in which
the second region includes a portion of the insulating film whose depth from the first surface is shallower than the depth at which the distance is minimized.
(3)

The light detection device according to (1), in which
the insulating film further includes a third region located in a portion of the insulating film whose depth from the first surface is shallower than the second region, and a dielectric constant of the third region is lower than the dielectric constant of the first region and higher than the dielectric constant of the second region.
(4)

The light detection device according to (3), in which
the insulating film further includes a fourth region located in a portion of the insulating film deeper than the second region, and a dielectric constant of the fourth region is higher than the dielectric constants of the first and second regions.
(5)

The light detection device according to (4), in which
the fourth region is divided into a plurality of regions in a depth direction from the first surface, and dielectric constants of the plurality of regions are higher in a region located at a deeper position.
(6)

The light detection device according to any one of (1) to (5), in which
a film thickness of a portion of the insulating film covering the inner side surface of the first trench is thinner toward the bottom of the first trench.
(7)

The light detection device according to any one of (1) to (5), in which
a film thickness of a portion of the insulating film covering an inner side surface of the first trench is thinner as the depth from the first surface is closer to the depth at which the second region is provided.
(8)

The light detection device according to any one of (1) to (7), in which
the second region is a region of the insulating film located in a portion whose depth from the first surface is shallower than a bottom surface of the first trench.
(9)

The light detection device according to any one of (1) to (8), including
a protective film covering a surface of the second region on the first surface side and a surface on an opposite side of the surface.
(10)

The light detection device according to (9), in which
the protective film further covers a surface of the second region on the inner side surface side of the first trench, and
a base film is provided between the protective film and the semiconductor substrate.
(11)

The light detection device according to any one of (1) to (10), in which
the first conductivity type is a P type and the second conductivity type is an N type, or
the first conductivity type is an N type and the second conductivity type is a P type.
(12)

A light detection device including:
a semiconductor substrate;
a first trench having a lattice shape and provided on a first surface of the semiconductor substrate;
a second trench having a lattice shape, provided at a bottom of the first trench and extending along the bottom;
an insulating film covering each of inner side surfaces of the first and second trenches and the first surface;
a photoelectric conversion region provided in an element region obtained by partitioning the semiconductor substrate by the first and second trenches, the photoelectric conversion region photoelectrically converting incident light to generate a charge;
a first semiconductor region provided in the element region and surrounding the photoelectric conversion region;
a first contact provided at the bottom of the first trench and in contact with the first semiconductor region;
a first electrode disposed in the first trench and in contact with the first contact;
a second semiconductor region provided in a region in contact with a surface of the first semiconductor region on the first surface side in the element region and having a first conductivity type same as a conductivity type of the first semiconductor region;
a third semiconductor region provided in a region in contact with a surface of the second semiconductor region on the first surface side in the element region and having a second conductivity type opposite to the first conductivity type;
a second contact provided on the first surface and in contact with the third semiconductor region; and
a second electrode in contact with the second contact, in which
a portion of the insulating film whose depth from the first surface is located at a depth at which a distance between the third semiconductor region and the first electrode is minimized is formed by using a low dielectric constant material having a relative dielectric constant of 3.5 or less.
(13)

An electronic device including
a light detection device including: a semiconductor substrate; a first trench having a lattice shape and provided on a first surface of the semiconductor substrate; a second trench having a lattice shape, provided at a bottom of the first trench and extending along the bottom; an insulating film covering each of inner side surfaces of the first and second trenches and the first surface; a photoelectric conversion region provided in an element region obtained by partitioning the semiconductor substrate by the first and second trenches, the photoelectric conversion region photoelectrically converting incident light to generate a charge; a first semiconductor region provided in the element region and surrounding the photoelectric conversion region; a first contact provided at the bottom of the first trench and in contact with the first semiconductor region; a first electrode disposed in the first trench and in contact with the first contact; a second semiconductor region provided in a region in contact with a surface of the first semiconductor region on the first surface side in the element region and having a first conductivity type same as a conductivity type of the first semiconductor region; a third semiconductor region provided in a region in contact with a surface of the second semiconductor region on the first surface side in the element region and having a second conductivity type opposite to the first conductivity type; a second contact provided on the first surface and in contact with the third semiconductor region; and a second electrode in contact with the second contact, in which the insulating film includes at least a first region and a second region, the second region is a region including a portion whose depth from the first surface is located at a depth at which a distance between the third semiconductor region and the first electrode is minimized, and a dielectric constant of the second region is lower than a dielectric constant of the first region.
(14)

An electronic device including
a light detection device including: a semiconductor substrate; a first trench having a lattice shape and provided on a first surface of the semiconductor substrate; a second trench having a lattice shape, provided at a bottom of the first trench and extending along the bottom; an insulating film covering each of inner side surfaces of the first and second trenches and the first surface; a photoelectric conversion region provided in an element region obtained by partitioning the semiconductor substrate by the first and second trenches, the photoelectric conversion region photoelectrically converting incident light to generate a charge; a first semiconductor region provided in the element region and surrounding the photoelectric conversion region; a first contact provided at the bottom of the first trench and in contact with the first semiconductor region; a first electrode disposed in the first trench and in contact with the first contact; a second semiconductor region provided in a region in contact with a surface of the first semiconductor region on the first surface side in the element region and having a first conductivity type same as a conductivity type of the first semiconductor region; a third semiconductor region provided in a region in contact with a surface of the second semiconductor region on the first surface side in the element region and having a second conductivity type opposite to the first conductivity type; a second contact provided on the first surface and in contact with the third semiconductor region; and a second electrode in contact with the second contact, in which a portion of the insulating film whose depth from the first surface is located at a depth at which a distance between the third semiconductor region and the first electrode is minimized is formed by using a low dielectric constant material having a relative dielectric constant of 3.5 or less.

### REFERENCE SIGNS LIST

1 Electronic device
10 Solid-state imaging device
11 SPAD array unit
12 Drive circuit
13 Output circuit
14 Timing control circuit
20 SPAD pixel
21 Photodiode
22 Readout circuit
30 Imaging lens
40 Storage unit
50 Processor
71 Light receiving chip
72 Circuit chip
100 Semiconductor substrate
101 Element region
102 Photoelectric conversion region
103 P type semiconductor region
103a P type semiconductor region
104 N− type semiconductor region
105 P+ type semiconductor region
106 N+ type semiconductor region
107 Cathode contact
108 Anode contact
109 Well region
110 Element isolation portion
111 Insulating film
111a First region
111b Second region
111c Third region
111d Fourth region
111e Fifth region
111f Sixth region
111g Seventh region
112 Light shielding film
113 Pinning layer
114 Planarization film
115 Color filter
116 On-chip lens
117a First insulating film
117b Second insulating film
117c Third insulating film
117d Fourth insulating film
120 Wiring layer
121 Cathode electrode
122 Anode electrode
123 Interlayer insulating film
124 Wiring
125 Connection pad
126 Wiring
130 Amplification region
140 Interface
150 Interface
160 Protective film
170 Base film
A1 Opening
A2 Opening
A3 Opening
A4 Opening
A5 Opening
LD Pixel drive line
LS Output signal line
M1 Mask
M2 Mask
M3 Mask
M4 Mask

What is claimed is:

1. A light detection device, comprising:
a semiconductor substrate;
a first trench having a lattice shape and provided on a first surface of the semiconductor substrate;
a second trench having a lattice shape, provided at a bottom of the first trench and extending along the bottom;
an insulating film covering each of inner side surfaces of the first and second trenches and the first surface;
a photoelectric conversion region provided in an element region obtained by partitioning the semiconductor substrate by the first and second trenches, the photoelectric conversion region photoelectrically converting incident light to generate a charge;
a first semiconductor region provided in the element region and surrounding the photoelectric conversion region;
a first contact provided at the bottom of the first trench and in contact with the first semiconductor region;
a first electrode disposed in the first trench and in contact with the first contact;
a second semiconductor region provided in a region in contact with a surface of the first semiconductor region on the first surface side in the element region and having a first conductivity type same as a conductivity type of the first semiconductor region;
a third semiconductor region provided in a region in contact with a surface of the second semiconductor region on the first surface side in the element region and having a second conductivity type opposite to the first conductivity type;
a second contact provided on the first surface and in contact with the third semiconductor region; and
a second electrode in contact with the second contact, wherein
the insulating film includes at least a first region and a second region, the second region is a region including a portion whose depth from the first surface is located at a depth at which a distance between the third semiconductor region and the first electrode is minimized, and a dielectric constant of the second region is lower than a dielectric constant of the first region.

2. The light detection device according to claim 1, wherein
the second region includes a portion of the insulating film whose depth from the first surface is shallower than the depth at which the distance is minimized.

3. The light detection device according to claim 1, wherein
the insulating film further includes a third region located in a portion of the insulating film whose depth from the first surface is shallower than the second region, and a dielectric constant of the third region is lower than the dielectric constant of the first region and higher than the dielectric constant of the second region.

4. The light detection device according to claim 3, wherein
the insulating film further includes a fourth region located in a portion of the insulating film deeper than the second region, and a dielectric constant of the fourth region is higher than the dielectric constants of the first and second regions.

5. The light detection device according to claim 4, wherein
the fourth region is divided into a plurality of regions in a depth direction from the first surface, and dielectric constants of the plurality of regions are higher in a region located at a deeper position.

6. The light detection device according to claim 1, wherein
a portion of the insulating film covering the inner side surface of the first trench has a film thickness becoming thinner toward the bottom of the first trench.

7. The light detection device according to claim 1, wherein
a film thickness of at least a part of a portion of the insulating film covering an inner side surface of the first trench is thinner as the depth from the first surface is closer to the depth at which the second region is provided.

8. The light detection device according to claim 1, wherein
the second region is a region of the insulating film located in a portion whose depth from the first surface is shallower than a bottom surface of the first trench.

9. The light detection device according to claim 1, comprising
a protective film covering a surface of the second region on the first surface side and a surface on an opposite side of the surface.

10. The light detection device according to claim 9, wherein
the protective film further covers a surface of the second region on the inner side surface side of the first trench, and
a base film is provided between the protective film and the semiconductor substrate.

11. The light detection device according to claim 1, wherein
the first conductivity type is a P type and the second conductivity type is an N type, or
the first conductivity type is an N type and the second conductivity type is a P type.

12. A light detection device, comprising:
a semiconductor substrate;
a first trench having a lattice shape and provided on a first surface of the semiconductor substrate;
a second trench having a lattice shape, provided at a bottom of the first trench and extending along the bottom;
an insulating film covering each of inner side surfaces of the first and second trenches and the first surface;
a photoelectric conversion region provided in an element region obtained by partitioning the semiconductor substrate by the first and second trenches, the photoelectric conversion region photoelectrically converting incident light to generate a charge;
a first semiconductor region provided in the element region and surrounding the photoelectric conversion region;
a first contact provided at the bottom of the first trench and in contact with the first semiconductor region;
a first electrode disposed in the first trench and in contact with the first contact;
a second semiconductor region provided in a region in contact with a surface of the first semiconductor region on the first surface side in the element region and having a first conductivity type same as a conductivity type of the first semiconductor region;
a third semiconductor region provided in a region in contact with a surface of the second semiconductor region on the first surface side in the element region and having a second conductivity type opposite to the first conductivity type;
a second contact provided on the first surface and in contact with the third semiconductor region; and
a second electrode in contact with the second contact, wherein
a portion of the insulating film whose depth from the first surface is located at a depth at which a distance between the third semiconductor region and the first electrode is minimized is formed by using a low dielectric constant material having a relative dielectric constant of 3.5 or less.

13. An electronic device, comprising:
a light detection device including: a semiconductor substrate; a first trench having a lattice shape and provided on a first surface of the semiconductor substrate; a second trench having a lattice shape, provided at a bottom of the first trench and extending along the bottom; an insulating film covering each of inner side surfaces of the first and second trenches and the first surface; a photoelectric conversion region provided in an element region obtained by partitioning the semiconductor substrate by the first and second trenches, the photoelectric conversion region photoelectrically converting incident light to generate a charge; a first semiconductor region provided in the element region and surrounding the photoelectric conversion region; a first contact provided at the bottom of the first trench and in contact with the first semiconductor region; a first electrode disposed in the first trench and in contact with the first contact; a second semiconductor region provided in a region in contact with a surface of the first semiconductor region on the first surface side in the element region and having a first conductivity type same as a conductivity type of the first semiconductor region; a third semiconductor region provided in a region in contact with a surface of the second semiconductor region on the first surface side in the element region and having a second conductivity type opposite to the first conductivity type; a second contact provided on the first surface and in contact with the third semiconductor region; and a second electrode in contact with the second contact, in which the insulating film includes at least a first region and a second region, the second region is a region including a portion whose depth from the first surface is located at a depth at which a distance between the third semiconductor region and the first electrode is minimized, and a dielectric constant of the second region is lower than a dielectric constant of the first region.

14. An electronic device, comprising:
a light detection device including: a semiconductor substrate; a first trench having a lattice shape and provided on a first surface of the semiconductor substrate; a second trench having a lattice shape, provided at a bottom of the first trench and extending along the bottom; an insulating film covering each of inner side surfaces of the first and second trenches and the first surface; a photoelectric conversion region provided in an element region obtained by partitioning the semiconductor substrate by the first and second trenches, the photoelectric conversion region photoelectrically converting incident light to generate a charge; a first semiconductor region provided in the element region and surrounding the photoelectric conversion region; a first contact provided at the bottom of the first trench and in contact with the first semiconductor region; a first electrode disposed in the first trench and in contact with the first contact; a second semiconductor region provided in a region in contact with a surface of the first semiconductor region on the first surface side in the element region and having a first conductivity type same as a conductivity type of the first semiconductor region; a third semiconductor region provided in a region in contact with a surface of the second semiconductor region on the first surface side in the element region and having a second conductivity type opposite to the first conductivity type; a second contact provided on the first surface and in contact with the third semiconductor region; and a second electrode in contact with the second contact, in which a portion of the insulating film whose depth from the first surface is located at a depth at which a distance between the third semiconductor region and the first electrode is minimized is formed by using a low dielectric constant material having a relative dielectric constant of 3.5 or less.
